(19) United States
(12) Patent Application Publication
(10) Pub. No.: US 2015/0031218 A1
(43) Pub. Date: Jan. 29, 2015

(54) FILM FORMING PROCESS AND FILM FORMING APPARATUS

(71) Applicant: TOKYO ELECTRON LIMITED, Tokyo (JP)

(72) Inventor: Takayuki Karakawa, Miyagi (JP)

(73) Assignee: TOKYO ELECTRON LIMITED, Tokyo (JP)

(21) Appl. No.: 14/384,700

(22) PCT Filed: Mar. 7, 2013
(86) PCT No.: PCT/JP2013/056350

§ 371 Date: Sep. 12, 2014

(30) Foreign Application Priority Data
Mar. 15, 2012 (JP) 2012-058932

(51) Int. Cl. H01L 21/02; C23C 16/52; C23C 16/458; C23C 16/455; H01L 21/67; C23C 16/44

(52) U.S. Cl. CPC H01L 21/0228; H01L 21/0217; H01L 21/67017; C23C 16/4409; C23C 16/4584; C23C 16/45538; C23C 16/45544; C23C 16/52
USPC 438/792; 118/704

(57) ABSTRACT

In a film forming apparatus (10), plasma-assisted ALD sequences are carried out to form a nitride film on a substrate (W) through the nitration of the silicon (Si) resulting from dichlorosilane (DCS), and then the first to fourth gas-feeding processes and plasma-feeding processes are successively carried out as plasma-assisted post-treatment. The gas to be fed in the first to fourth gas-feeding processes in the plasma-assisted post-treatment is a modifier gas consisting of either a gas selected from among N₂, NH₃, Ar and H₂ or a mixed gas obtained by suitably mixing some of these gases. After the completion of the plasma-assisted ALD sequences, a plasma formed from the modifier gas is fed onto the nitride film on the substrate (W) to improve the film quality of the nitride film.

### TECHNICAL FIELD

The present disclosure relates to a film forming process and a film forming apparatus.

### BACKGROUND

As a method of forming a film on a substrate of a silicon wafer, an atomic layer deposition (ALD) method or a molecular layer deposition (MLD) method has been conventionally known in which a radical reaction is used. In the ALD method or the MLD method, a precursor gas is injected to a surface of a substrate so that atoms or molecules of the precursor gas are adsorbed on the surface of the substrate. Then, a purge gas is injected to the surface of the substrate so as to remove atoms or molecules excessively chemically adsorbed on the surface of the substrate.

Then, plasma of a reaction gas is supplied to the surface of the substrate from which the chemically adsorbed atoms or molecules have been removed. Then, the atoms or molecules of the precursor gas adsorbed on the surface of the substrate react with free radicals of the reaction gas which are generated by the plasma, thereby forming a film on the substrate of the silicon wafer.

In the ALD method or the MLD method, the above-described film forming steps are repeatedly performed so that a film obtained by the radical reaction of the atoms or molecules of the precursor gas is deposited to a required film thickness on the substrate of the silicon wafer. For example, when the precursor gas is dichlorosilane (DCS), and the reaction gas is N₂ (nitrogen), a silicon nitride film is formed on the substrate of the silicon wafer.

### PRIOR ART DOCUMENT

### Patent Document

Patent Document 1: Japanese Patent Laid-Open Publication No. 2011-210872
Patent Document 2: Japanese Patent Laid-Open Publication No. 2002-368084

### DISCLOSURE OF THE INVENTION

### Problems to be Solved

However, in the above-described conventional technology, a film quality on or near the surface of the silicon nitride film formed on the substrate of the silicon wafer is degraded as compared to a film quality in the film under the surface. This is because the surface of the silicon nitride film is oxidized by being exposed to atmosphere after the film is formed.

Accordingly, an exemplary embodiment of the present disclosure has been made in consideration of the above described problems, and an object thereof is to improve a film quality of a silicon nitride film.

### Means to Solve the Problems

According to an aspect of an exemplary embodiment of the present disclosure, in a film forming process, a film is formed on a surface of a substrate by a film forming apparatus. First, a precursor gas is chemically adsorbed on the surface of the substrate mounted on a mounting table provided within a hermetically sealed processing container. Then, a reaction gas is supplied into the processing container to generate plasma of the reaction gas, and the plasma of the reaction gas is reacted with the surface of the substrate. Then, a modifier gas which is any gas of an ammonia gas, an argon gas, a nitrogen gas, and a hydrogen gas, or a gas obtained by mixing the ammonia gas, the argon gas, the nitrogen gas, and the hydrogen gas is supplied into the processing container, plasma of the modifier gas is generated, and the plasma of the modifier gas is reacted with the surface of the substrate.

### Effect of the Invention

According to an aspect of an exemplary embodiment of the present disclosure, a film quality of a silicon nitride film formed on a substrate is improved.

### BRIEF DESCRIPTION OF THE DRAWINGS

FIG. 1 is a top plan view schematically illustrating a film forming apparatus according to a first exemplary embodiment.

FIG. 2 is a plan view illustrating the film forming apparatus illustrated in FIG. 1 in a state where a top portion of a processing container is removed.

FIG. 3 is a vertical cross-sectional view of the film forming apparatus along the line A-A of FIGS. 1 and 2.

FIG. 4 is a vertical cross-sectional view of a left portion of the film forming apparatus of FIG. 3 with reference to a vertical axis X in an enlarged scale.

FIG. 5 is a vertical cross-sectional view of a right portion of the film forming apparatus of FIG. 3 with reference to the vertical axis X in an enlarged scale.

FIG. 6 is a view illustrating an outline of a film forming process according to the first exemplary embodiment.

FIG. 7 is a view illustrating details of the film forming process according to the first exemplary embodiment.

FIG. 8 is a view illustrating an outline of a film forming process according to a second exemplary embodiment.

FIG. 9 is a view illustrating details of the film forming process according to the second exemplary embodiment.

FIG. 10 is a vertical cross-sectional view of a film forming apparatus according to a third exemplary embodiment.

FIG. 11 is a view illustrating details of a film forming process according to the third exemplary embodiment.

FIG. 12 is a view illustrating details of a film forming process according to a fourth exemplary embodiment.

FIG. 13 is a view illustrating a relationship between a DHF treatment time and a film thickness.

FIG. 14A is a view illustrating a test recipe related to Example 1.

FIG. 14B is a view illustrating the test recipe related to Example 1.

FIG. 14C is a view illustrating the test recipe related to Example 1.

FIG. 15A is a view illustrating a relationship between a pressure and a WERR in a plasma post-treatment.

FIG. 15B is a view illustrating a relationship between a pressure and a mean film thickness in the plasma post-treatment.

FIG. 15C is a view illustrating a relationship between a microwave power and a WERR in the plasma post-treatment.

FIG. 15D is a view illustrating a relationship between a microwave power and a mean film thickness in the plasma post-treatment.

FIG. 16A is a view illustrating a relationship between a WERR and a plasma post-treatment time when a modifier gas is NH₃/N₂/Ar.

FIG. 16B is a view illustrating a relationship between a mean film thickness, film thickness uniformity and a plasma post-treatment time when a modifier gas is NH₃/N₂/Ar.

FIG. 16C is a view illustrating a relationship between a WERR and a plasma post-treatment time when a modifier gas is NH₃/Ar.

FIG. 16D is a view illustrating a relationship between a mean film thickness, film thickness uniformity and a plasma post-treatment time when a modifier gas is NH₃/Ar.

FIG. 16E is a view illustrating a relationship between a WERR and a plasma post-treatment time when a modifier gas is N₂/Ar.

FIG. 16F is a view illustrating a relationship between a mean film thickness, a film thickness uniformity and a plasma post-treatment time when a modifier gas is N₂/Ar.

FIG. 16G is a view illustrating a relationship between a WERR and a plasma post-treatment time when a modifier gas is Ar.

FIG. 16H is a view illustrating a relationship between a mean film thickness, a film thickness uniformity and a plasma post-treatment time when a modifier gas is Ar.

FIG. 17A is a view illustrating a modifying depth of a nitride film by a plasma post-treatment.

FIG. 17B is a view illustrating a relationship between a DHF treatment time and a film thickness.

FIG. 18A is a view illustrating a relationship between a waveform separation of Si 2p 3/2 spectrum and a TOA in Example 1.

FIG. 18B is a view for explaining TOA.

FIG. 19A is a view illustrating a relationship between a peak area of Si 2p 3/2 spectrum of Si—NH and a TOA in Example 1.

FIG. 19B is a view illustrating a relationship between a peak area of Si 2p 3/2 spectrum of Si—H and a TOA in Example 1.

FIG. 19C is a view illustrating a relationship between a peak area of Si 2p 3/2 spectrum of Si—OH and a TOA in Example 1.

FIG. 20 is a view illustrating a change of a WERR by a plasma post-treatment.

FIG. 21A is a view illustrating an outline of oxidation of a nitride film in a case in which there is no plasma post-treatment.

FIG. 21B is a view illustrating an outline of termination of dangling bonds on a nitride film in a case in which there is a NH₃/Ar plasma post-treatment.

FIG. 21C is a view illustrating an outline of termination of dangling bonds on a nitride film in a case in which there is an Ar plasma post-treatment.

FIG. 22A is a view illustrating changes of WERR1 and WERR2 in each of a comparative sample and a test sample when a plasma supply time of a plasma ALD sequence was set to 10 sec.

FIG. 22B is a view illustrating changes of WERR1 and WERR2 in each of a comparative sample and a test sample when a plasma supply time of a plasma ALD sequence was set to 30 sec.

FIG. 22C is a view illustrating changes of WERR1 and WERR2 in each of a comparative sample and a test sample when a plasma supply time of a plasma ALD sequence was set to 60 sec.

FIG. 23 is a view illustrating a plasma supply time in a plasma ALD sequence, and changes of WERR1 and WERR2.

FIG. 24A is a view illustrating a test recipe related to Example 2.

FIG. 24B is a view illustrating a test recipe related to Example 2.

FIG. 25A is a view illustrating a comparison in WERR between Ar plasma and N₂ plasma in a DCS adsorption pre-treatment.

FIG. 25B is a view illustrating a comparison in film thickness average between Ar plasma and N₂ plasma in a DCS adsorption pre-treatment.

FIG. 25C is a view illustrating a comparison in film thickness uniformity between Ar plasma and N₂ plasma in a DCS adsorption pre-treatment.

FIG. 25D is a view illustrating a comparison in film thickness distribution between Ar plasma and N₂ plasma in a DCS adsorption pre-treatment.

FIG. 26 is a view illustrating a relationship between a waveform separation of Si 2p 3/2 spectrum and a TOA in Example 2.

FIG. 27A is a view illustrating a relationship between a peak area of Si 2p 3/2 spectrum of Si—NH and a TOA in Example 2.

FIG. 27B is a view illustrating a relationship between a peak area of Si 2p 3/2 spectrum of Si—H and a TOA in Example 2.

FIG. 27C is a view illustrating a relationship between a peak area of Si 2p 3/2 spectrum of Si—OH and a TOA in Example 2.

FIG. 28 is a view illustrating a comparison in a ratio of a peak area of Si 2p 3/2 spectrum in each constitutional component of a nitride film between a case where Ar plasma was employed and a case where N₂ plasma was employed in a DCS adsorption pre-treatment.

FIG. 29A is a view illustrating a comparison in WERR between a sample obtained by performing a plasma ALD treatment for 10 sec without a DCS adsorption pre-treatment, a sample obtained by performing a plasma ALD treatment for 15 sec without a DCS adsorption pre-treatment, and a sample obtained by performing a DCS adsorption pre-treatment for 5 sec and a plasma ALD treatment for 10 sec.

FIG. 29B is a view illustrating a comparison in film thickness average between a sample obtained by performing a plasma ALD treatment for 10 sec without a DCS adsorption pre-treatment, a sample obtained by performing a plasma ALD treatment for 15 sec without a DCS adsorption pre-treatment, and a sample obtained by performing a DCS adsorption pre-treatment for 5 sec and a plasma ALD treatment for 10 sec.

FIG. 29C is a view illustrating a comparison in film thickness uniformity between a sample obtained by performing a plasma ALD treatment for 10 sec without a DCS adsorption pre-treatment, a sample obtained by performing a plasma ALD treatment for 15 sec without a DCS adsorption pre-treatment, and a sample obtained by performing a DCS adsorption pre-treatment for 5 sec and a plasma ALD treatment for 10 sec.

FIG. 29D is a view illustrating a comparison in film thickness distribution between a sample obtained by performing a plasma ALD treatment for 10 sec without a DCS adsorption pre-treatment, a sample obtained by performing a plasma ALD treatment for 15 sec without a DCS adsorption pre-treatment, and a sample obtained by performing a DCS adsorption pre-treatment for 5 sec and a plasma ALD treatment for 10 sec.

FIG. 30 is a view illustrating a comparison of test results in Example 2.

FIG. 31 is a view illustrating a test recipe related to Example 3.

FIG. 32 is a view illustrating a relationship between a film uniformity and a film thickness in Tests 3 to 5.

FIG. 33 is a view illustrating a film thickness distribution in Test 3 by contour lines.

FIG. 34 is a view illustrating a film thickness distribution in Test 4 by contour lines.

FIG. 35 is a view illustrating a film thickness distribution in Test 5 by contour lines.

### DETAILED DESCRIPTION TO EXECUTE THE INVENTION

Hereinafter, film forming processes and film forming apparatuses according to exemplary embodiments of the present disclosure will be described with reference to drawings. In the following descriptions of exemplary embodiments with reference to the respective drawings, identical or corresponding elements will be given the same reference numerals. Also, the following exemplary embodiments and the drawings referred in the exemplary embodiments are exemplary only and are not intended to limit the present disclosure. Also, the following exemplary embodiments may be properly combined as long as they do not contradict each other.

### First Exemplary Embodiment

### Configuration of Film Forming Apparatus According to First Exemplary Embodiment

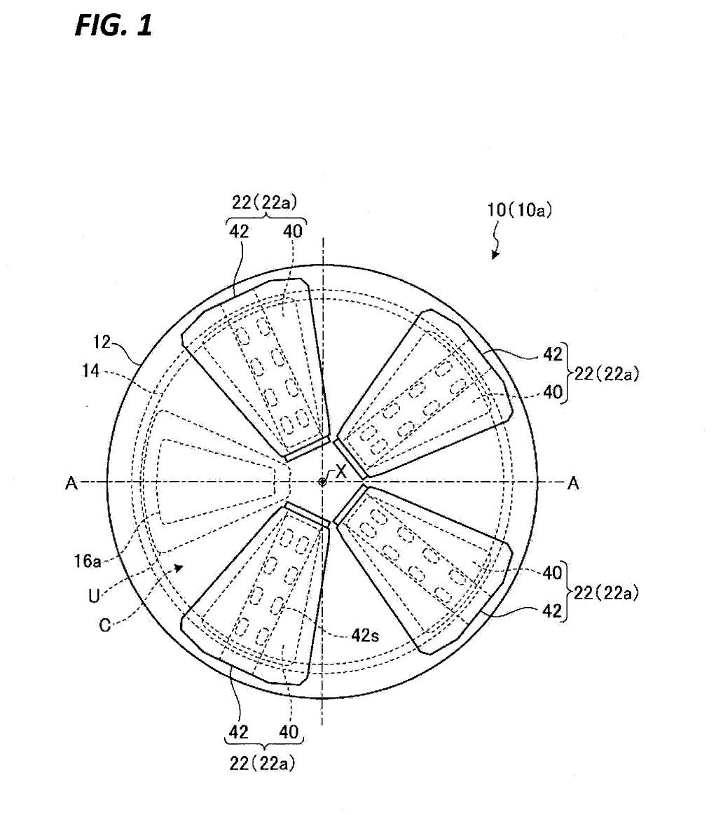

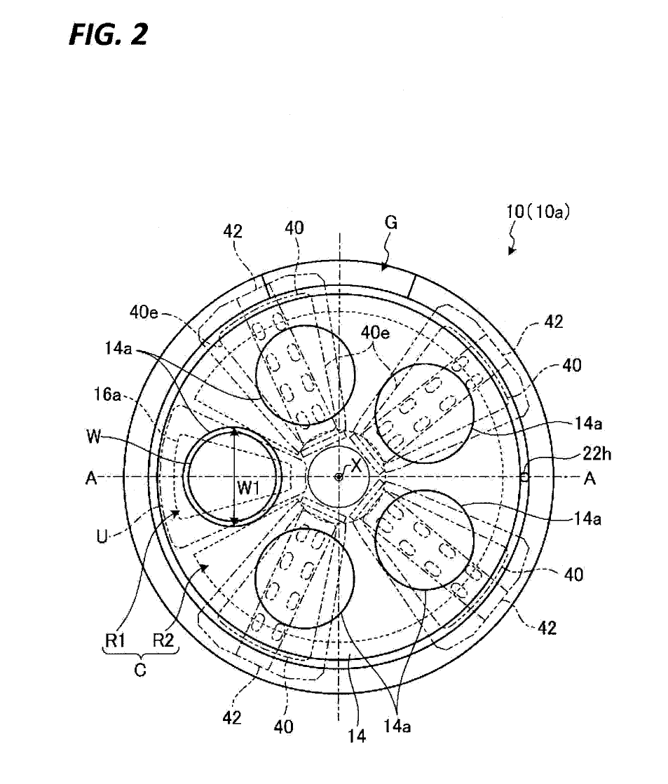

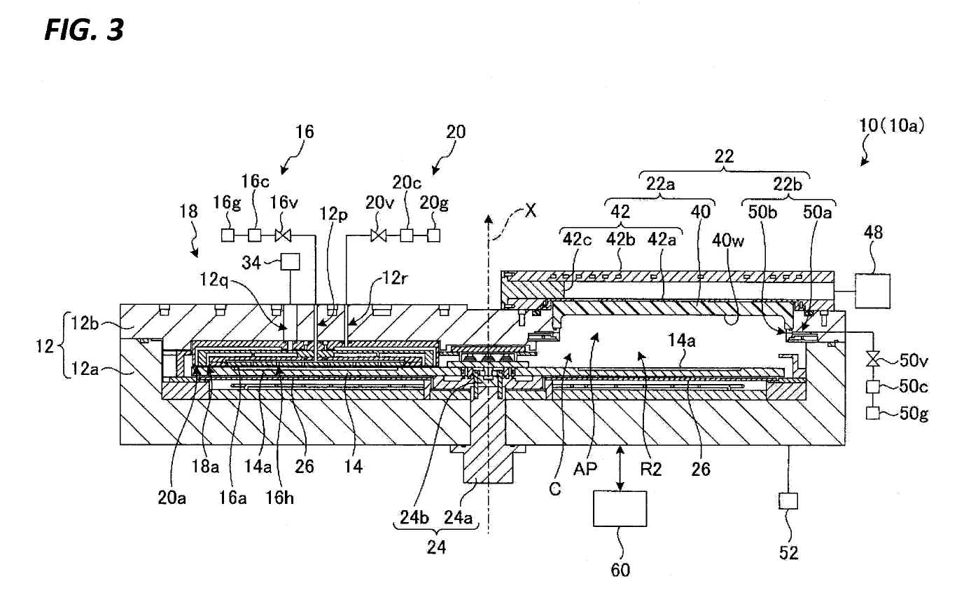

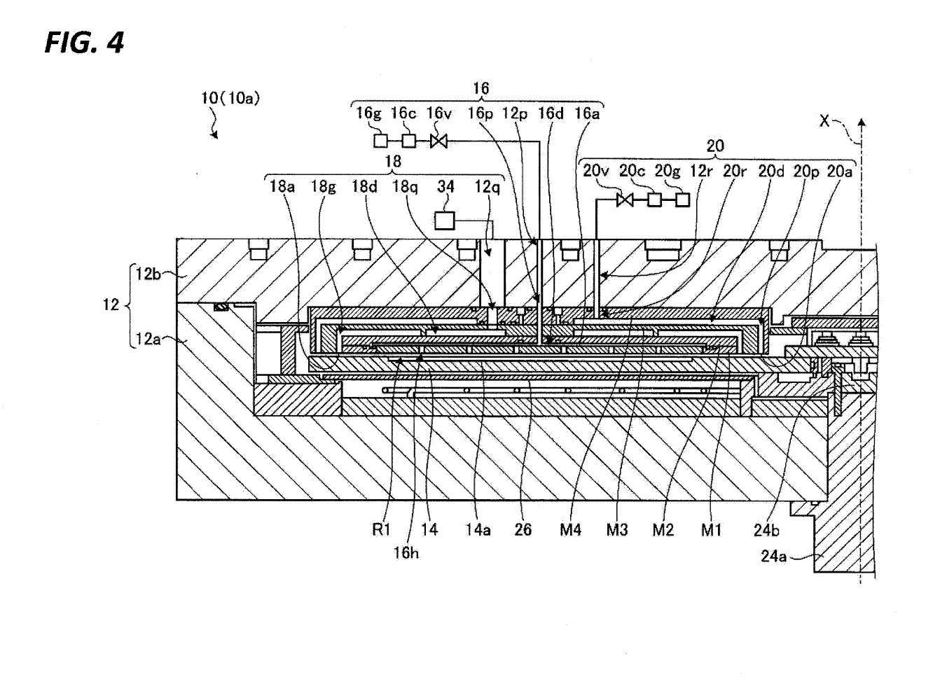

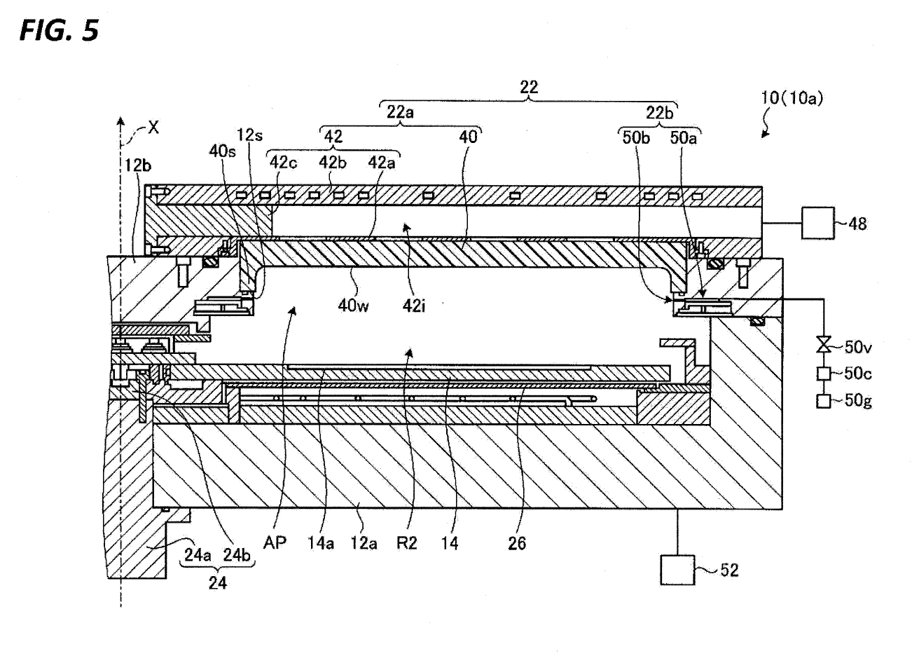

Referring to FIGS. 1 to 5, a configuration of a film forming apparatus according to a first exemplary embodiment will be described. FIG. 1 is a top plan view schematically illustrating the film forming apparatus according to the first exemplary embodiment. FIG. 2 is a plan view illustrating the film forming apparatus illustrated in FIG. 1 in a state where a top portion of a processing container is removed. FIG. 3 is a vertical cross-sectional view of the film forming apparatus along the line A-A of FIGS. 1 and 2. FIG. 4 is a vertical cross-sectional view illustrating the left portion of the film forming apparatus of FIG. 3 with reference to the vertical axis X in an enlarged scale. FIG. 5 is a vertical cross-sectional view illustrating the right portion of the film forming apparatus of FIG. 3 with reference to the vertical axis X in an enlarged scale. A film forming apparatus 10 illustrated in FIGS. 1 to 5 includes, as main elements, a processing container 12, a mounting table 14, a first gas supply section 16, an exhaust section 18, a second gas supply section 20, and a plasma generating section 22.

As illustrated in FIG. 1, the film forming apparatus 10 includes the processing container 12. The processing container 12 is a substantially cylindrical container with a vertical axis X as a central axis. The processing container 12 includes a processing chamber C provided therein. The processing chamber C includes a unit U provided with an injection section 16a. The processing container 12 is made of a metal such as, for example, Al (aluminum), and has an inner surface which has been subjected to an anti-plasma treatment such as, for example, an alumite treatment or a thermal spray treatment of Y₂O₃ (yttrium oxide).

The film forming apparatus 10 includes plasma generating sections 22 at the top of the processing container 12. The plasma generating sections 22 are provided in four consecutive regions, respectively, among five fan-shaped regions of a substantially circular surface at the top of the processing container 12, the fan-shaped regions being substantially equally divided around the vertical axis X. Each plasma generating section 22 includes an antenna 22a configured to output microwaves. The antenna 22a includes a dielectric plate 40 provided therein. The antenna 22a includes a waveguide 42 provided on the dielectric plate 40.

For the convenience of explanation, in FIG. 1, a plasma generating section 22 located adjacent to the unit U in a clockwise direction will be referred to as a first plasma generating section. A plasma generating section 22 located adjacent to the first plasma generating section in a clockwise direction will be referred to as a second plasma generating section. Likewise, a plasma generating section 22 located adjacent to the second plasma generating section in a clockwise direction will be referred to as a third plasma generating section. Likewise, a plasma generating section 22 located adjacent to the third plasma generating section in a clockwise direction will be referred to as a fourth plasma generating section.

The number of divided regions of the substantially circular surface at the top of the processing container 12, the number of the plasma generating sections 22 provided therein, and the unit U, and the locations of the first to fourth plasma generating sections may be properly varied without being limited to those illustrated in FIGS. 1 and 2.

As illustrated in FIG. 2, the film forming apparatus 10 includes a mounting table 14 which includes a plurality of substrate mounting regions 14a on the top surface thereof. The mounting table 14 is a substantially disk-shaped plate member with the vertical axis X as a central axis. On the top surface of the mounting table 14, a recessed portion on which a substrate W may be mounted is formed. A plurality of recessed portions (here, five recessed portions) is flat and is formed concentrically. The substrate W is disposed within one of the recessed portions, and is supported not to be deviated when rotated. The substrate mounting regions 14a are arranged along the circumference having the vertical axis X as the central axis. Each substrate mounting region 14a is a substantially circular recessed portion having substantially the same shape as that of a substantially circular substrate W. The diameter W1 of the recessed portion of each substrate mounting region 14a is substantially the same as the diameter of the substrate W mounted on the substrate mounting region 14a. That is, the diameter W1 of the recessed portion of each substrate mounting region 14a may be roughly set such that the mounted substrate W is fitted in the recessed portion to be fixed without being moved from the fitted position by a centrifugal force even if the mounting table 14 is rotated.

The film forming apparatus 10 includes a gate valve G at the outer periphery of the processing container 12. The gate valve G is configured to allow a substrate W to be carried into and out of the processing chamber C therethrough, using a conveyance device such as, for example, a robot arm. The film forming apparatus 10 includes an exhaust port 22h at the bottom of the outer periphery of the mounting table 14. The film forming apparatus 10 maintains the pressure within the processing chamber C at a target pressure by the exhaust from the exhaust port 22h.

As illustrated in FIG. 3, the processing container 12 includes a lower member 12a and an upper member 12b. The lower member 12a is formed in a substantially tubular shape with a top opening, and forms a recessed portion which includes a side wall and a bottom wall that forms a processing chamber C. The upper member 12b is a lid body which is formed in a substantially tubular shape, and covers the top opening of the recessed portion of the lower member 12a to form the processing chamber C. An elastic sealing member such as, for example, an O ring configured to seal the processing chamber C may be provided at the outer periphery between the lower member 12a and the upper member 12b.

The film forming apparatus 10 includes the mounting table 14 within the processing chamber C formed by the processing container 12. The mounting table 14 is driven to be rotated around the vertical axis X by a driving mechanism 24. The driving mechanism 24 includes a driving device 24a such as, for example, a motor, and a rotation shaft 24b, and is attached to the lower member 12a of the processing container 12.

The rotation shaft 24b extends into the processing chamber C with the vertical axis X as a central axis. The rotation shaft 24b rotates in, for example, a clockwise direction around the vertical axis X by a driving force transferred from the driving device 24a. A central portion of the mounting table 14 is supported by the rotation shaft 24b. Accordingly, the mounting table 14 is rotated around the vertical axis X according to the rotation of the rotation shaft 24b. An elastic sealing member such as, for example, an O ring configured to seal the processing chamber C may be provided between the lower member 12a of the processing container 12 and the driving mechanism 24.

The film forming apparatus 10 includes a heater 26 below the mounting table 14 within the processing chamber C. The heater 26 is configured to heat a substrate W mounted on the substrate mounting region 14a. Specifically, the heater 26 heats the mounting table 14 so as to heat the substrate W. The substrate W is conveyed into processing chamber C by the conveyance device (not illustrated) such as, for example, a robot arm through the gate valve G provided in the processing container 12, and mounted on the substrate mounting region 14a. The substrate W is taken out of the processing chamber C by the conveyance device through the gate valve G.

The processing chamber C forms a first region R1 (no number is denoted in FIG. 3) and a second region R2 arranged in a plane on the circumference around the vertical axis X. The substrate W mounted on the substrate mounting region 14a passes through the first region R1 and the second region R2 while the mounting table 14 is rotated.

As illustrated in FIG. 4, in the film forming apparatus 10, the first gas supply section 16 is disposed above the first region R1 to face the top surface of the mounting table 14. The first gas supply section 16 includes the injection section 16a. That is, a region included in the processing chamber C, which faces the injection section 16a, is the first region R1.

The injection section 16a includes a plurality of injection ports 16h. The first gas supply section 16 supplies a precursor gas to the first region R1 through the plurality of injection ports 16h. When the precursor gas is supplied to the first region R1, atoms or molecules of the precursor gas are chemically adsorbed on the surface of the substrate W which passes through the first region R1. The precursor gas is, for example, dichlorosilane (DCS), monochlorosilane, or trichlorosilane. When the precursor gas is DCS, Si (silicon) is chemically adsorbed on the surface of the substrate W.

Exhaust ports 18a of the exhaust section 18 are provided above the first region R1 to face the top surface of the mounting table 14. The exhaust ports 18a are provided around the injection section 16a. The exhaust section 18 exhausts a gas within the processing chamber C by operating an exhaust device 34 such as, for example, a vacuum pump, through the exhaust ports 18a.

An injection port 20a of the second gas supply section 20 is provided above the first region R1 to face the top surface of the mounting table 14. The injection port 20a is provided around the exhaust port 18a. The second gas supply section 20 supplies a purge gas to the first region R1 through the injection ports 20a. The purge gas supplied by the second gas supply section 20 is an inert gas such as, for example, argon (Ar). When the purge gas is injected to the surface of the substrate W, the atoms or molecules (remaining gas components) of the precursor gas excessively chemically adsorbed on the substrate W are removed from the substrate W. Accordingly, an atomic layer or a molecular layer in which the atoms or molecules of the precursor gas are chemically adsorbed is formed on the surface of the substrate W.

The film forming apparatus 10 injects the purge gas from the injection port 20a, and exhausts the purge gas from the exhaust port 18a along the surface of the mounting table 14. Accordingly, the precursor gas supplied to the first region R1 is suppressed from being leaked to the outside of the first region R1. Also, since the film forming apparatus 10 inject the purge gas from the injection port 20a, and exhausts the purge gas from the exhaust port 18a along the surface of the mounting table 14, for example, a reaction gas supplied to the second region R2 or radicals of the reaction gas may be suppressed from infiltrating into the first region R1. That is, the film forming apparatus 10 forms a configuration in which the first region R1 and the second region R2 are separated from each other through the injection of the purge gas from the second gas supply section 20, and the operation of the exhaust section 18.

The film forming apparatus 10 includes the unit U which includes the injection section 16a, the exhaust port 18a, and the injection port 20a. That is, the injection section 16a, the exhaust port 18a, and the injection port 20a are formed as a portion constituting the unit U. As illustrated in FIG. 4, the unit U is constituted by sequentially stacking a first member M1, a second member M2, a third member M3, and a fourth member M4. The unit U is attached to the processing container 12 to be abutted on the bottom surface of the upper member 12b of the processing container 12.

As illustrated in FIG. 4, a gas supply path 16p penetrating the second member M2 to the fourth member M4 is formed in the unit U. The upper end of the gas supply path 16p is connected to a gas supply path 12p formed in the upper member 12b of the processing container 12. A gas supply source 16g of the precursor gas is connected to the gas supply path 12p through a valve 16v and a flow rate controller 16c such as, for example, a mass flow controller. The lower end of the gas supply path 16p is connected to a space 16d formed between the first member M1 and the second member M2. The space 16d is connected to the injection ports 16h of the injection section 16a provided in the first member M1.

A gas supply path 20r penetrating the second member M2 to the fourth member M4 is formed in the unit U. The upper end of the gas supply path 20r is connected to a gas supply path 12r formed in the upper member 12b of the processing container 12. A gas supply source 20g of the reaction gas is connected to the gas supply path 12r through a valve 20v and a flow rate controller 20c such as, for example, a mass flow controller.

In the unit U, the lower end of the gas supply path 20r is connected to a space 20d formed between the bottom surface of the fourth member M4 and the top surface of the third member M3. The fourth member M4 forms a recessed portion which accommodates the first to third members M1 to M3. A gap 20p is formed between the side surface of the third member M3 and the side surface of the fourth member M4 which forms the recessed portion. The gap 20p is connected to the space 20d.

An exhaust path 18q penetrating the third member M3 and the fourth member M4 is formed in the unit U. The upper end of the exhaust path 18q is connected to an exhaust path 12q formed in the upper member 12b of the processing container 12. The exhaust path 12q is connected to the exhaust device 34 such as, for example, a vacuum pump. The lower end of the exhaust path 18q is connected to a space 18d formed between the bottom surface of the third member M3 and the top surface of the second member M2.

The third member M3 includes a recessed portion which accommodates the first member M1 and the second member M2. A gap 18g is formed between the side end faces of the first member M1 and the second member M2, and the inner side surface of the third member M3 which forms the recessed portion provided in the third member M3. The gap 18g is connected to the space 18d. The lower end of the gap 18g serves as the exhaust port 18a. The film forming apparatus 10 injects the purge gas from the injection port 20a, and exhausts the purge gas from the exhaust port 18a along the surface of the mounting table 14 so that the precursor gas supplied to the first region R1 is suppressed from being leaked to the outside of the first region R1.

As illustrated in FIG. 5, the film forming apparatus 10 includes the plasma generating section 22 above the second region R2 as an opening of the upper member 12b, such that the plasma generating section 22 faces the top surface of the mounting table 14. As illustrated in FIG. 2, the plasma generating section 22 has an opening formed in a substantially fan shape. In the upper member 12b, four openings are formed, and the film forming apparatus 10 includes, for example, four plasma generating sections 22.

The plasma generating section 22 supplies a reaction gas and microwaves to the second region R2 so as to generate plasma of the reaction gas in the second region R2. When a nitrogen-containing gas is used as the reaction gas, the atomic layer or molecular layer chemically adsorbed on the substrate W is nitrated. As for the reaction gas, a nitrogen-containing gas such as, for example, N₂ (nitrogen) or NH₃ (ammonia) may be used.

The plasma generating section 22 supplies a modifier gas and microwaves to the second region R2 to generate plasma of the modifier gas in the second region R2. By the plasma of the modifier gas, in the second region R2, the nitride film of the substrate W may be modified. As for the modifier gas, for example, any one of N₂, NH₃, Ar (argon), and H₂ (hydrogen), or a mixed gas obtained by appropriately mixing these gases may be used. During the process of modifying the nitride film of the substrate W by the plasma generating section 22 in the second region R2, the supply of the precursor gas into the first region R1 is stopped.

As illustrated in FIG. 5, the dielectric plate 40 of the plasma generating section 22 is air-tightly disposed to close an opening AP. The waveguide 42 is disposed on the dielectric plate 40 and has an inner space 42i formed therein to allow the microwaves to be propagated therethrough. The waveguide 42 and the top surface of the dielectric plate 40 constitute an antenna 22a configured to supply the microwaves to the second region R2. The dielectric plate 40 is a substantially plate-shaped member made of a dielectric material such as, for example, SiO₂ (quartz). The dielectric plate 40 is provided to face the second region R2. The dielectric plate 40 is supported by the upper member 12b of the processing container 12.

As illustrated in FIG. 5, in the upper member 12b of the processing container 12, the opening AP is formed to expose the dielectric plate 40 to the second region R2. The plane size of the top portion of the opening AP is larger than the plane size of the bottom portion of the opening AP. The plane size refers to a cross-sectional area of a plane perpendicular to the vertical axis X. An L-shaped stepped surface 12s is formed in the portion of the upper member 12b which forms the opening AP. The edge of the dielectric plate 40 serves as a supported portion 40s, and hermetically abuts on the stepped surface 12s by, for example, an O ring. When the supported portion 40s abuts on the stepped surface 12s, the dielectric plate 40 is supported by the upper member 12b.

In the dielectric plate 40 supported by the upper member 12b, the portion facing the mounting table 14 through the second region R2, that is, the portion facing the second region R2, serves as a dielectric window 40w. The waveguide 42 is provided on the dielectric plate 40 so that the inner space 42i extends in a substantially radial direction in relation to the vertical axis X.

A slot plate 42a is a metallic plate member. The slot plate 42a forms a bottom surface of the inner space 42i. The slot plate 42a comes in contact with and covers the top surface of the dielectric plate 40. The slot plate 42a includes a plurality of slot holes 42s in the portion forming the inner space 42i.

A metallic top member 42b is provided above the slot plate 42a to cover the slot plate 42a. The top member 42b forms the top surface of the inner space 42i of the waveguide 42. The top member 42b is fixedly screwed to the upper member 12b so that the slot plate 42a and the dielectric plate 40 are sandwiched between the top member 42b and the upper member 12b of the processing container 12.

An end member 42c is a metallic member. The end member 42c is provided at one longitudinal end of the waveguide 42. That is, the end member 42c is attached to one end of the slot plate 42a and the top member 42b so as to close one end of the inner space 42i. A microwave generator 48 is connected to the other end of the waveguide 42.

The microwave generator 48 generates microwaves of, for example, about 2.45 GHz, and supplies the generated microwaves to the waveguide 42. The microwaves generated by the microwave generator 48 are propagated within the inner space 42 of the waveguide 42, and supplied to the second region R2 through the dielectric window 40 by passing through the slot holes 42s of the slot plate 42a and transmitting through the dielectric plate 40.

The modifier gas is any gas of N₂, NH₃, Ar, and H₂, or a mixed gas obtained by appropriately mixing these gases. A third gas supply section 22b is formed at the inner periphery side of the opening of the upper member 12b. The third gas supply section 22b includes a gas supply path 50a and an injection port 50b.

The gas supply path 50a is formed within the upper member 12b of the processing container 12 so as to extend around the opening AP. The injection port 50b configured to inject a reaction gas or a modifier gas toward a portion below the dielectric window 40w is formed to be communicated with the gas supply path 50a. A gas supply source 50g of the reaction gas or the modifier gas is connected to the gas supply path 50a through a valve 50v and a flow rate controller 50c such as, for example, a mass flow controller.

That is, the plasma generating section 22 supplies the reaction gas or the modifier gas to the second region R2 by the third gas supply section 22b, and supplies the microwaves to the second region R2 by the antenna 22a. Accordingly, plasma of the reaction gas or the modifier gas is generated in the second region R2.

As illustrated in FIG. 3, the angle range in which the second region R2 extends in the circumferential direction of the vertical axis X is set to be larger than the angle range in which the first region R1 extends in the circumferential direction. Accordingly, due to the plasma of the reaction gas or the modifier gas generated in the second region R2, the atomic layer or molecular layer adsorbed on the substrate W is exposed to the plasma for a long time to be efficiently processed. For example, the Si layer adsorbed on the substrate W is nitrated by free radicals of N₂.

As illustrated in FIG. 2, the exhaust port 22h is formed at the bottom side of the outer periphery of the mounting table 14 in the lower member 12a of the processing container 12. An exhaust device 52 is connected to the exhaust port 22h. The film forming apparatus 10 maintains the pressure within the second region R2 at a target pressure by the exhaust from the exhaust port 22h through an operation of the exhaust device 52.

As illustrated in FIG. 3, the film forming apparatus 10 includes a control unit 60 configured to control respective elements of the film forming apparatus 10. The control unit 60 may be a computer including, for example, a control device such as a central processing unit (CPU), a storage device such as a memory, and an input/output device. When the CPU is operated according to a control program stored in the memory, the control unit 60 controls the respective elements of the film forming apparatus 10.

The control unit 60 transmits a control signal for controlling a rotation speed of the mounting table 14 to the driving device 24a. The control unit 60 transmits a control signal for controlling the temperature of the substrate W to a power supply unit connected to the heater 26. The control unit 60 transmits a control signal for controlling a flow rate of the precursor gas to the valve 16v and the flow rate controller 16c. The control unit 60 transmits a control signal for controlling the displacement volume of the exhaust device 34 connected to the exhaust port 18a, to the exhaust device 34.

The control unit 60 transmits a control signal for controlling the flow rate of the purge gas to the valve 20v and the flow rate controller 20c. The control unit 60 transmits a control signal for controlling the power of microwaves to the microwave generator 48. The control unit 60 transmits a control signal for controlling the flow rate of the reaction gas to the valve 50v and the flow rate controller 50c. The control unit 60 transmits a control signal for controlling the displacement volume from the exhaust devices 34 and 52, to the exhaust devices.

### Outline of Film Forming Process According to First Exemplary Embodiment

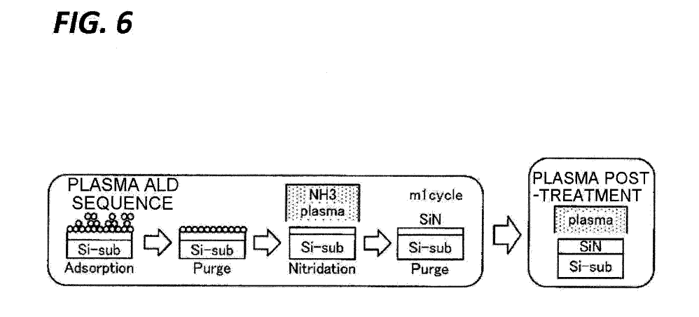

FIG. 6 is a view illustrating an outline of a film forming process according to the first exemplary embodiment. As illustrated in FIG. 6, in a plasma atomic layer deposition (ALD) sequence, first, the film forming apparatus 10 injects DCS which is a precursor gas to a surface of a Si-sub (substrate) which is a substrate W. Accordingly, the film forming apparatus 10 causes Si included in DCS to be adsorbed on the Si-Sub. Then, the film forming apparatus 10 injects an inert gas such as, for example, N₂ which is a purge gas to the surface of the Si-sub. Accordingly, the film forming apparatus 10 purges (removes) Si (remaining gas) excessively chemically adsorbed on the surface of the Si-sub. When Si excessively chemically adsorbed on the surface of the Si-sub is removed, a chemically adsorbed Si layer remains on the surface of the Si-sub. The pressure within the processing container is preferably 5 Torr or more. This increases the adsorption efficiency in relation to the substrate.

Then, the film forming apparatus 10 supplies plasma together with a reaction gas such as, for example, NH₃ to the surface of the Si-sub from which the excessively chemically adsorbed Si has been removed so as to nitrate the surface of the Si-sub (the adsorbed Si layer). Then, SiN (silicon nitride) is formed on the surface of the Si-sub (the adsorbed Si layer). Then, the film forming apparatus 10 injects an inert gas such as, for example, N₂ to the surface of the Si-sub formed with SiN to perform purging. Thus, the impurities are purged from the surface of the Si-sub.

The film forming apparatus 10 repeats the plasma ALD sequence including a series of processes as described above, for (m1) cycles. Here, m1 is a natural number and refers to the number of repetitions of the plasma ALD sequence until the film thickness of SiN formed on the surface of the Si-sub becomes a required film thickness. The film forming apparatus 10 supplies plasma together with a modifier gas which is any gas of N₂, NH₃, Ar, and H₂, or a mixed gas obtained by appropriately mixing these gases, to the surface of the Si-sub formed with SiN.

That is, the film forming apparatus 10 performs one cycle of the plasma ALD sequence as illustrated in FIG. 6 so as to form a nitride film with a film thickness of, for example, one atom or one molecule. Then, the film forming apparatus 10 repeatedly performs the plasma ALD sequence until the nitride film arrives at, for example, 5 nm (nanometers). Then, the film forming apparatus 10 performs a plasma post-treatment illustrated in FIG. 6. By the plasma post-treatment, the film forming apparatus 10 improves the film quality of the nitride film formed by the plasma ALD sequence.

### Details of Film Forming Process According to First Exemplary Embodiment

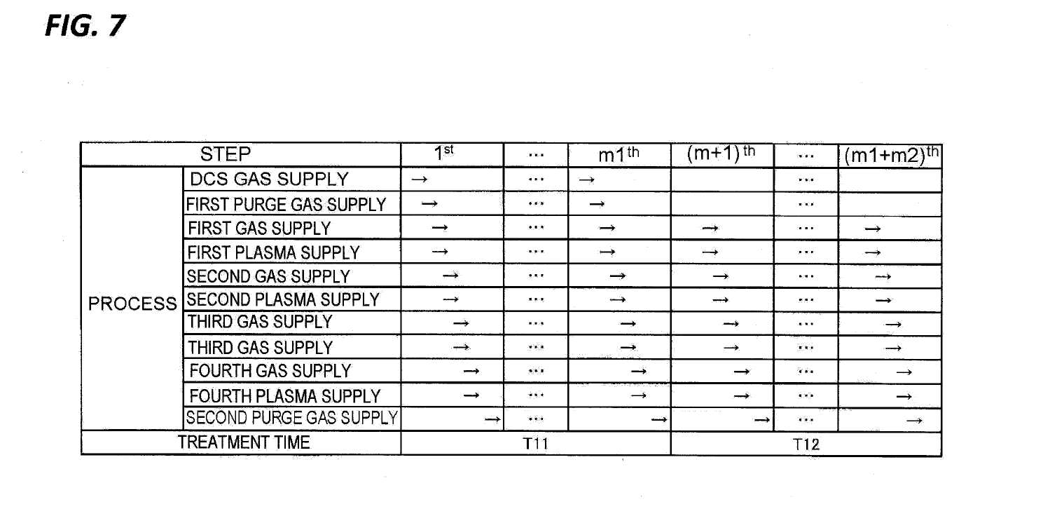

FIG. 7 is a view illustrating details of the film forming process according to the first exemplary embodiment. In a pre-treatment of the film forming process, the film forming apparatus 10 conveys a Si substrate W to the substrate mounting region 14a of the mounting table 14 by the conveyance device such as, for example, a robot arm, through the gate valve G. The film forming apparatus 10 rotates the mounting table 14 by the driving mechanism 24 so that the substrate mounting region 14a on which the substrate W is mounted is rotated and moved in relation to the second region R2 as a base point.

The film forming apparatus 10 supplies a reaction gas including N₂ to the second region R2 by the third gas supply section 22b. The film forming apparatus 10 supplies microwaves output from the microwave generator 48, to the second region R2 through the antenna 22a. Accordingly, in the second region R2, plasma of the reaction gas is generated. Then, by the plasma of the reaction gas, the surface of the substrate W is nitrated. The above-described process is the pre-treatment of the film forming process. The pre-treatment is called initial nitration.

Then, as illustrated in FIG. 7, the film forming apparatus 10 performs 1^{st} to m1^{th} film forming-modifying steps. Here, m1 is a natural number and refers to the number of repetitions of a step until a required film thickness is obtained through the film forming process by the film forming apparatus 10. Each step includes a process in which a DCS gas supply, a first purge gas supply, first to fourth supplies of a modifier gas and plasma, and a second purge gas supply are sequentially performed. FIG. 7 illustrates that respective processes in 1^{st} step are sequentially performed, and then the same steps are repeated m1 times. One rotation of the mounting table 14 in the film forming apparatus 10 corresponds to one step.

That is, the film forming apparatus 10 rotates the mounting table 14 so that the substrate W is moved into the first region R1. First, the film forming apparatus 10, in the DCS gas supply process of the 1^{st} step, supplies a DCS gas as a precursor gas to the first region R1 by the first gas supply section 16. Accordingly, Si included in DCS is chemically adsorbed on the substrate W.

Then, the film forming apparatus 10 rotates the mounting table 14 so that the substrate W passes through a gap between the first region R1 and the second region R2. Here, the film forming apparatus 10, in the first purge gas supply process of the 1^{st} step, injects a purge gas supplied by the second gas supply section 20 to the surface of the substrate W. Accordingly, Si excessively chemically adsorbed on the substrate W is removed.

Then, the film forming apparatus 10 rotates the mounting table 14 so that the substrate W is moved into the second region R2. The film forming apparatus 10 supplies a reaction gas including N₂ to the second region R2 by the third gas supply section 22b of the first plasma generating section. The film forming apparatus 10 supplies microwaves from the microwave generator 48 of the first plasma generating section to the second region R2 through the antenna 22a. Accordingly, plasma of the reaction gas is generated in the second region R2.

That is, in the first gas supply process and the first plasma supply process of the 1^{st} step, the atomic layer or the molecular layer adsorbed on the surface of the substrate W is nitrated by plasma of the reaction gas generated by the first plasma generating section. Likewise, the film forming apparatus 10 further rotates the mounting table 14, and performs the same processes as the first gas supply process and the first plasma supply process in the 1^{st} step by the second to fourth plasma generating sections.

Then, the film forming apparatus 10 rotates the mounting table 14 so that the substrate W passes through the gap between the second region R2 and the first region R1. Here, the film forming apparatus 10, in the second purge gas supply process of the 1^{st} step, injects a purge gas supplied by the second gas supply section 20 to the substrate W. As described above, all the processes in the 1^{st} step are completed. Then, the film forming apparatus 10 performs 2^{nd} to m^{th} steps which are the same as the 1^{st} step. The processing in the 1^{st} to m1^{th} steps is a plasma ALD sequence.

In this manner, the film forming apparatus 10 rotates the mounting table 14 so that the plasma ALD sequence is repeatedly performed m1 times on the substrate W. Accordingly, a silicon nitride film is formed on the substrate W to a required film thickness.

Then, the film forming apparatus 10 rotates the mounting table 14 and performs a (m1+1)^{th} step in which first to fourth gas and plasma supply processes are sequentially performed. The gas supplied in the first to fourth gas supply processes in the (m1+1)^{th} step is a modifier gas which is any one of N₂, NH₃, Ar, and H₂, or a mixed gas obtained by appropriately mixing these gases.

Then, the film forming apparatus 10 rotates the mounting table 14 so that the substrate W passes through the gap between the second region R2 and the first region R1. Here, the film forming apparatus 10, in the second purge gas supply process of the (m1+1)^{th} step, injects a purge gas supplied by the second gas supply section 20 to the substrate W. Accordingly, the gas remaining on the substrate W is removed. As described above, the (m1+1)^{th} step is completed.

The film forming apparatus 10 repeats the same step as the (m1+1)^{th} step until a (m1+m2)^{th} step. Here, m2 is a natural number and refers to the number of repetitions of the same step as the (m1+1)^{th} step until the film quality of the nitride film on the surface of the substrate W reaches a target film quality. The (m1+1)^{th} to (m1+m2)^{th} steps are called a plasma post-treatment.

As illustrated in FIG. 7, a treatment time T11 in which the film forming apparatus 10 performs the plasma ALD sequence, and a treatment time T12 in which the film forming apparatus 10 performs the plasma post-treatment may be properly varied by the control of the rotation speed of the mounting table 14 by the control unit 60.

### Effect of First Exemplary Embodiment

According to the first exemplary embodiment, the film forming apparatus 10 performs an adsorption step in which a precursor gas chemically adsorbed on the surface of a substrate mounted on a mounting table provided within a hermetically sealed processing container. The film forming apparatus 10 performs a first reaction step in which a reaction gas is supplied into the processing container to generate plasma of the reaction gas, and the plasma of the reaction gas is reacted with the surface of the substrate. The film forming apparatus 10 performs a second reaction step in which a modifier gas, which is any gas of an ammonia gas, an argon gas, a nitrogen gas, and a hydrogen gas, or a mixed gas obtained by mixing these gases, is supplied into the processing container, generating plasma of the modifier gas, and the plasma of the modifier gas is reacted with the surface of the substrate. Accordingly, a throughput of producing a nitride film on the substrate is increased and the film quality of the nitride film is improved. Also, the nitride film may be formed on the plate with a high coverage.

The film forming apparatus 10 performs the second reaction step after sequentially repeatedly performing the adsorption step and the first reaction step, thereby efficiently improving the film quality of the nitride film.

The film forming apparatus 10 repeatedly performs a series of treatments in the second reaction step after sequentially repeatedly performing the adsorption step and the first reaction step, thereby securing the film thickness of the nitride film, and efficiently improving the film quality of the nitride film.

The film forming apparatus 10 continuously performs the plasma ALD sequence and the plasma post-treatment on the substrate W mounted on the mounting table 14 by rotation of the mounting table 14. The film forming apparatus 10 is capable of controlling the treatment time T11 and T12. Accordingly, the throughput of the film forming process is further improved by the film forming apparatus 10.

The film forming apparatus 10 may perform a series of plasma ALD sequence processes and the plasma post-treatment subsequent to the plasma ALD sequence processes, several times. That is, assuming that a series of plasma ALD sequence processes and the plasma post-treatment is regarded as one treatment, the film forming apparatus 10 may perform the treatment several times. The film forming apparatus 10 performs a 1^{st} plasma post-treatment on a nitride film of, for example, 5 nm which is formed on the substrate W by a 1^{st} series of plasma ALD sequence processes. Then, the film forming apparatus 10 performs a 2^{nd} series of plasma ALD sequence processes on the substrate W which has been subjected to the 1^{st} plasma post-treatment. Then, a nitride film of, for example, 5 nm is additionally formed on the substrate W. The film forming apparatus 10 performs a 2^{nd} plasma post-treatment (a plasma modifying treatment) on the nitride film of 5 nm additionally formed on the substrate W by the 1^{st} series of plasma ALD sequence processes. In this manner, a modified nitride film may be laminated on the substrate W for example, at every 5 nm, and a nitride film of high quality may be efficiently formed. Meanwhile, in one plasma ALD sequence, a nitride film of, for example, 10 nm may be formed on the substrate W, and the plasma post-treatment may be performed on the nitride film of 10 nm formed on the substrate W by the plasma ALD sequence.

In the plasma ALD sequence and the plasma post-treatment, the same gas may be used. Then, a switching between a gas to be supplied in the plasma ALD sequence and a gas to be supplied in the plasma post-treatment may be omitted, and thus the process efficiency is improved. Also, different gases may be supplied from first to fourth plasma generators (the plasma generating section 22), respectively. Then, the switching between a gas to be supplied in the plasma ALD sequence and a gas to be supplied in the plasma post-treatment may be omitted while generating plasma of an appropriate mixed gas. When the different gases are supplied from the first to fourth plasma generators (the plasma generating section 22), respectively, the film forming apparatus 10 stops gas supply from the plasma generating section 22 which supplies a gas not included in the mixed gas while the gases are mixed to obtain a reaction gas or a modifier gas.

### Second Exemplary Embodiment

The configuration of the film forming apparatus in the second exemplary embodiment is the same as that of the first exemplary embodiment. The second exemplary embodiment is different from the first exemplary embodiment in that in the plasma ALD sequence, the DCS adsorption pre-treatment to be described below is performed prior to the DCS adsorption treatment to be described below. Hereinafter, a film forming process by a film forming apparatus according to the second exemplary embodiment will be described.

### Outline of Film Forming Process According to Second Exemplary Embodiment

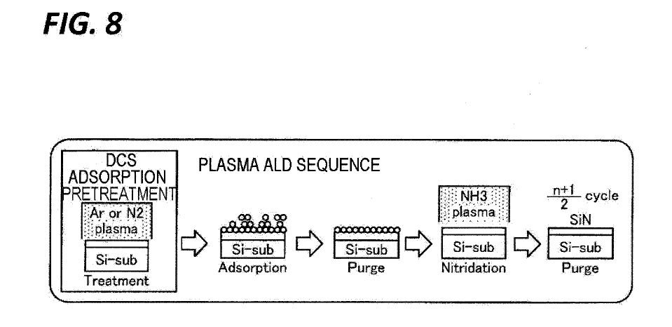

FIG. 8 is a view illustrating an outline of a film forming process according to a second exemplary embodiment. The pre-treatment of the film forming process is the same as that in the first exemplary embodiment. In the film forming process according to the second exemplary embodiment, prior to the plasma ALD sequence illustrated in FIG. 8, initial nitration is performed so as to produce a nitride film on the surface of a Si-sub as a substrate W by plasma of Ar or N₂.

Then, as illustrated in FIG. 8, the film forming apparatus 10a supplies plasma together with a reaction gas of a modifier gas which is any gas of Ar and N₂, or a mixed gas obtained by appropriately mixing these gases to the surface of the Si-sub formed with a SiN film. This processing is called a DCS adsorption pre-treatment. Next, the film forming apparatus 10a injects DCS to the surface of the Si-sub (SiN film) so that Si included in DCS is adsorbed. Then, the film forming apparatus 10a injects an inert gas such as, for example, N₂ to the surface of the Si-sub (Si layer) so as to purge Si (remaining gas) excessively chemically adsorbed on the surface of the Si-sub (Si layer). When Si excessively chemically adsorbed on the surface of the Si-sub is removed, a chemically adsorbed Si layer remains on the surface of the Si-sub.

Then, the film forming apparatus 10a supplies plasma together with a reaction gas such as, for example, NH₃ to the surface of the Si-sub (Si layer) from which the excessively chemically adsorbed Si has been removed so as to nitrate the Si layer adsorbed on the surface of the Si-sub. Then, a SiN film is formed on the surface of the Si-sub. Then, the film forming apparatus 10a injects an inert gas such as, for example, N₂ to the surface of the Si-sub formed with the SiN film to purge the impurities (for example, residues) from the surface of the Si-sub. Meanwhile, the treatment from adsorption to purging is called a DCS adsorption treatment.

The above-described step is repeated for (n+1)/2 cycles. Here, n is a natural number, and the step is repeated for (n+1)/2 cycles until the film thickness of SiN formed on the surface of the Si-sub reaches a target film thickness. After the step is repeated for (n+1)/2 cycles, the film forming process of the Si-sub is completed. In the second exemplary embodiment, one plasma ALD sequence illustrated in FIG. 8 includes two treatments, that is, the DCS adsorption pre-treatment and the DCS adsorption treatment. That is, the film forming apparatus 10a performs the DCS adsorption pre-treatment by one rotation of the mounting table 14, and performs the DCS adsorption treatment by another rotation. Accordingly, two rotations of the mounting table 14 correspond to one cycle of the plasma ALD sequence of the second exemplary embodiment.

That is, in the first exemplary embodiment, after the plasma ALD sequence, a plasma treatment is performed by a modifier gas. Meanwhile, in the film forming process according to the second exemplary embodiment, the plasma treatment by the modifier gas is included in one cycle of the plasma ALD sequence. That is, each time a nitride film layer of one atom or one molecule is formed on the surface of the Si-sub by one cycle of the plasma ALD sequence, the plasma treatment is performed by the modifier gas.

That is, the film forming apparatus 10a performs the plasma ALD sequence including the DCS adsorption pre-treatment, multiple times. In the 1^{st} plasma ALD sequence, the film forming apparatus 10a performs a DCS adsorption pre-treatment on the nitride film of, for example, one atom or one molecule, which is formed on the substrate W. Then, the film forming apparatus 10a performs a 2^{nd} plasma ALD sequence on the substrate W which has been subjected to a 1^{st} plasma post-treatment. Then, a nitride film of, for example, one atom or one molecule, is further formed on the substrate W. The film forming apparatus 10a may repeat the plasma ALD sequence including the DCS adsorption pre-treatment so as to laminate a modified nitride film on the substrate W, for example, at every thickness of 1 atom or 1 molecule.

### Details of Film Forming Process According to Second Exemplary Embodiment

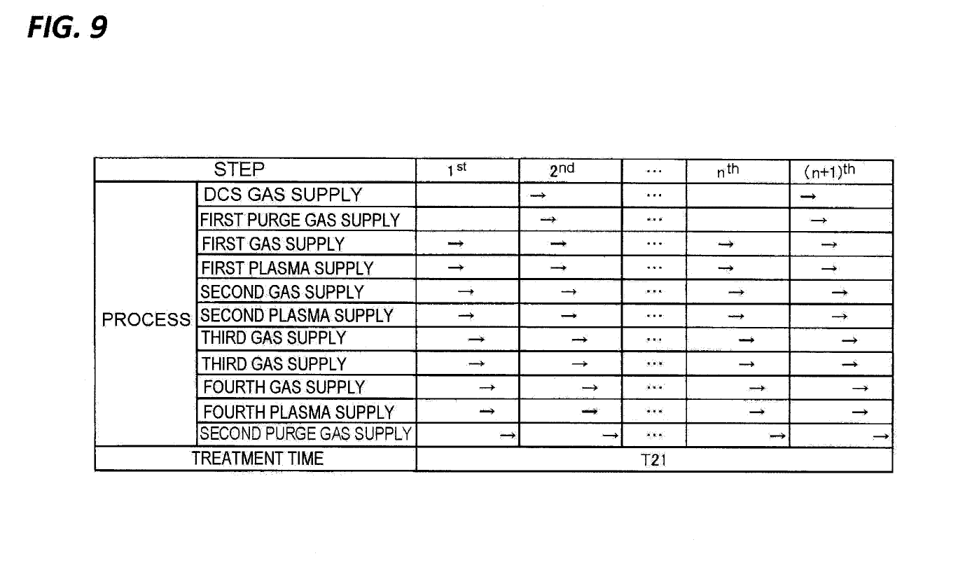

FIG. 9 is a view illustrating details of the film forming process according to the second exemplary embodiment. The pre-treatment of the film forming process 10a according to the second exemplary embodiment is the same as that of the first exemplary embodiment. As illustrated in FIG. 9, the film forming apparatus 10a sequentially performs, first to fourth gas and plasma supply processes in a 1^{st} step, in the same manner as in the (m1+1)^{th} step of the first exemplary embodiment. Then, the film forming apparatus 10a sequentially performs a second purge gas supply process in the 1^{st} step. The gas supplied in the first to fourth gas supply processes in the 1^{st} step is a modifier gas which is the same as that of the first exemplary embodiment. The 1^{st} day step is called a DCS adsorption pre-step.

The film forming apparatus 10a performs the same step as the 1^{st} step in the first exemplary embodiment, as a 2^{nd} step. The 2^{nd} step is called a DCS adsorption step. The film forming apparatus 10a sequentially performs the DCS adsorption pre-step and the DCS adsorption step which are the same as 1^{st} and 2^{nd} steps, until n^{th} to (n+1)^{th} steps. Here, n is a natural number, and refers to the number of repetitions of the DCS adsorption pre-step and the DCS adsorption step until the nitride film of a target film quality is formed through the film forming process by the film forming apparatus 10a.

A time T21 in which the film forming apparatus 10a performs 1^{st} to (n+1)^{th} steps may be properly varied by the control of the rotation speed of the mounting table 14 by the control unit 60. The film forming apparatus 10a according to the second exemplary embodiment continuously performs the plasma ALD sequence including the DCS adsorption pre-treatment, on the substrate W mounted on the mounting table 14, by rotating the mounting table 14. The film forming apparatus 10a is capable of controlling the treatment time T21. Accordingly, the throughput of the film forming process is further improved by the film forming apparatus 10a.

That is, the film forming apparatus 10a performs the plasma ALD sequence including the DCS adsorption pre-treatment illustrated in FIG. 8, for 1 cycle, thereby forming a nitride film with a film thickness of, for example, 1 atom or 1 molecule. Then, the film forming apparatus 10a repeatedly performs the plasma ALD sequence until the nitride film is formed to, for example, 5 nm (nanometers). By the plasma post-treatment, the film forming apparatus 10a may efficiently form the nitride film of high quality.

### Effect of Second Exemplary Embodiment

According to the second exemplary embodiment as described above, the film forming apparatus 10a performs an adsorption step in which a precursor gas is adsorbed on the surface of a substrate mounted on a mounting table provided within a hermetically sealed processing container. The film forming apparatus 10a performs a first reaction step in which a reaction gas is supplied into the processing container to generate plasma of the reaction gas, and the plasma of the reaction gas is reacted with the surface of the substrate. The film forming apparatus 10a performs a second reaction step in which an argon gas and a nitrogen gas are supplied into the processing container, ions or radicals of the modifier gas are generated by plasma, and the plasma of the modifier gas is reacted with the surface of the substrate. The film forming apparatus 10a sequentially and repeatedly performs a series of treatments of the adsorption step, the first reaction step and the second reaction step by rotating the mounting table 14, so that the film quality of a nitride film may be modified at every film thickness of, for example, 1 atom or 1 molecule, and a nitride film of higher quality may be efficiently formed.

### Third Exemplary Embodiment

### Configuration of Film Forming Apparatus According to Third Exemplary Embodiment

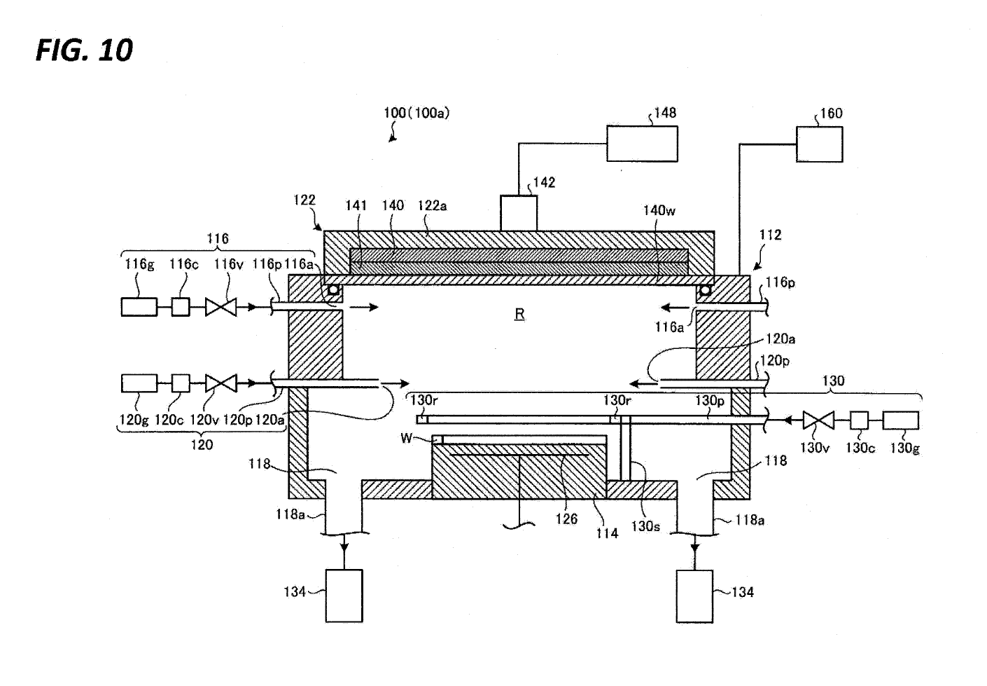

FIG. 10 is a vertical cross-sectional view of a film forming apparatus according to a third exemplary embodiment. A film forming apparatus 100 according to the third exemplary embodiment has the same function as that of the film forming apparatus 10 according to the first and second exemplary embodiments. The film forming apparatus 10 according to the first and second exemplary embodiments pass a substrate through a processing chamber radially partitioned into respective processing areas for processes, by rotating the mounting table 14. Accordingly, a series of processes and steps is continuously performed on the substrate. In contrast, the film forming apparatus 100 according to the third exemplary embodiment supplies a gas to be used for a treatment in each process or step to the substrate on a mounting table of a processing chamber which is not partitioned and exhausts the gas after the treatment.

The film forming apparatus 100 includes a processing container 112 formed in, for example, a bottomed-cylindrical shape with an opened top. The processing container 112 is made of, for example, an aluminum alloy. The processing container 112 is grounded. A mounting table 114 on which, for example, a substrate W is mounted is provided in a substantially central portion of the bottom of the processing container 112.

A heater 126 is embedded in the mounting table 114. The heater 126 is connected to a DC power supply (not illustrated) provided outside of the processing container 112. The heater 126 is heated by the DC power supply so as to heat the substrate W mounted on the mounting table 114.

A dielectric window 140w is provided on the top opening of the processing container 112 through an elastic sealing member such as, for example, an O ring configured to seal a region R within the processing container 112. The processing container 112 is closed by the dielectric window 140w. A plasma generating section 122 configured to supply microwaves for generating plasma is provided on the top of the dielectric window 140w.

In the plasma generating section 122, a disk-shaped slot plate 141 formed with a plurality of slots is provided on the top of the dielectric window. A dielectric plate (a slow wave plate) 140 formed of a low-loss dielectric material and configured to delay microwaves is provided on the top of the slot plate 141 within an antenna 122a. A cover member is disposed to cover the antenna 122a and the slow wave plate.

On the top surface of the plasma generating section 122, a waveguide 142 lead to a microwave generator 148 is connected to the cover member. The microwave generator 148 generates microwaves.

The microwave generator 148 generates microwaves of, for example, about 2.45 GHz, and supplies the generated microwaves to the waveguide 142. When the microwaves generated by the microwave generator 148 and propagated in the waveguide 142 are propagated to the antenna 122a, the microwaves are propagated through the dielectric plate 140 and supplied into the region R within the processing container 112 through slot holes of the slot plate 141 and the dielectric window 140w.

Gas supply ports 116a are formed in the upper portion of the inner peripheral surface of the processing container 112 which covers the outer periphery of the region R. The gas supply ports 116a are uniformly formed at a plurality of locations along, for example, the inner peripheral surface of the processing container 112. A gas supply path 116p communicated with a gas supply source 116g provided outside the processing container 112 is connected to the gas supply ports 116a through, for example, the side wall portion of the processing container 112.

The gas supply source 116g is connected to the gas supply path 116p through a valve 116v and a flow rate controller 116c such as, for example, a mass flow controller. Since a gas supply section 116 is configured to include the gas supply ports 116a, the flow rate controller 116c, the gas supply path 116p, and the valve 116v, a gas may be supplied to the region R within the processing container 112 from the upper side.

Gas supply ports 120a are formed in the middle portion of the inner peripheral surface of the processing container 112 which covers the outer periphery of the region R. The gas supply ports 120a are formed at a plurality of locations along, for example, the inner peripheral surface of the processing container 112. A gas supply path 120p communicated with a gas supply source 120g provided at the outside of the processing container 112 is connected to the gas supply ports 120a through, for example, the side wall portion of the processing container 112.

The gas supply source 120g is connected to the gas supply path 120p through a valve 120v and a flow rate controller 120c such as, for example, a mass flow controller. Since a gas supply section 120 is configured to include the gas supply ports 120a, the flow rate controller 120c, the gas supply path 120p, and the valve 120v, a gas may be supplied to the region R within the processing container 112 from the lateral side.

A gas supply ring 130r having a substantially annular shape is formed above the mounting table 114 at a position where the gas supply ring 130r is disposed to surround the outer periphery of the substrate W mounted on the mounting table 114. The gas supply ring 130r is, for example, a substantially annular gas pipe. A plurality of gas supply holes are formed on the surface of the pipe of the gas supply ring 130r. The gas supply holes are configured to supply a gas to the substrate W on the mounting table 114 from the upper side of the outer periphery of the substrate W. A gas supply path 130p communicated with a gas supply source 130g provided at the outside of the processing container 112 is connected to the gas supply ring 130r through, for example, the side wall portion of the processing container 112. The gas supply ring 130r is supported by a support column 130s to be substantially parallel to the mounting table 114 and the substrate W on the mounting table 114.

The gas supply source 130g is connected to the gas supply path 130p through a valve 130v and a flow rate controller 130c such as, for example, a mass flow controller. Since a gas supply section 130 is configured to include the gas supply ring 130r, the flow rate controller 130c, the gas supply path 130p, and the valve 130v, a gas may be supplied to the substrate W on the mounting table 114 within the processing container 112 from the upper side of the outer periphery of the substrate W at a near distance. The gas supply ring 130r is also called an ALD ring.

Gases supplied from the gas supply sources 116g, 120g and 130g are a precursor gas, a purge gas, a reaction gas, and a modifier gas. These gases are stored in their respective gas sources, and supplied to the region R via flow rate controllers and valves by switching paths from the respective gas sources. Alternatively, the gases may be supplied to the region R via their respective gas sources, and flow rate controllers. The precursor gas, the purge gas, the reaction gas, and the modifier gas are the same as those in the first and second exemplary embodiments.

Exhaust sections 118 configured to exhaust the gas within the region R are provided at both sides of the bottom of the processing container 112 with the mounting table 114 interposed between the exhaust sections 118. Each of the exhaust sections 118 exhausts the gas within the region R through an exhaust port 118a by an operation of an exhaust device 134 such as a vacuum pump. By the exhaust from the exhaust port 118a, the pressure within the region R is maintained at a target pressure.

### Details of Film Forming Process According to Third Exemplary Embodiment

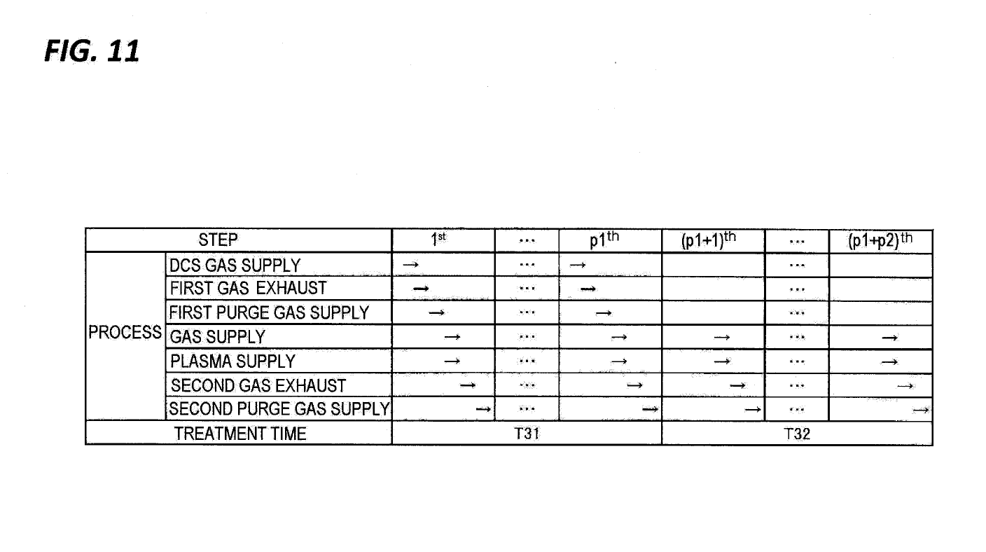

FIG. 11 is a view illustrating details of a film forming process according to the third exemplary embodiment. The outline of the film forming process according to the third exemplary embodiment is the same as that of the first exemplary embodiment. However, the film forming process according to the third exemplary embodiment is different from that of the first exemplary embodiment in that in each process and each step, a gas to be used for a treatment is supplied and the gas is exhausted after the treatment.

In a pre-treatment of the film forming process, a substrate W is mounted on the mounting table 114 of the film forming apparatus 100, and the region R is covered with a cover. The film forming apparatus 100 supplies a reaction gas including N₂ to the region R by the gas supply source 116g. The film forming apparatus 100 supplies microwaves output from the microwave generator 148 to the region R through the plasma generating section 122. Accordingly, in the region R, plasma of the reaction gas is generated. By the plasma of the reaction gas, the surface of the substrate W is nitrated. This is the pre-treatment of the film forming process. The pre-treatment is called initial nitration.

Next, as illustrated in FIG. 11, the film forming apparatus 100 sequentially performs 1^{st} to p1^{th} steps. Here, p1 is a natural number and refers to the number of repetitions of a step until a target film thickness is formed through the film forming process by the film forming apparatus 100. Each step includes respective processes in which a DCS gas supply, a first gas exhaust, a first purge gas supply, a gas supply, a plasma supply, a second gas exhaust, and a second purge gas supply are sequentially performed. FIG. 11 illustrates that respective processes in the 1^{st} step are sequentially performed, and then the same step is repeated until the p1^{th} step.

That is, first, the film forming apparatus 100, in the DCS gas supply process of the 1^{st} step, supplies a DCS gas as a precursor gas to the region R by the gas supply section 116. Accordingly, Si included in DCS is chemically adsorbed on the substrate W.

Next, the film forming apparatus 100, in the first gas exhaust process of the 1^{st} step, exhausts the gas within the region R by the exhaust device 134 so that the region R is placed in a vacuum state. Next, the film forming apparatus 100, in the first purge gas supply process of the 1^{st} step, injects a purge gas supplied by the gas supply section 116 to the substrate W. Accordingly, Si excessively chemically adsorbed on the substrate W is removed.

Next, in the first gas supply process of the 1^{st} step, the film forming apparatus 100 supplies a reaction gas including N₂ to the region R by the gas supply section 116. In the plasma supply process of the 1^{st} step, the film forming apparatus 100 supplies microwaves from the microwave generator 148 to the plasma generating section 122 through the antenna 122a. Accordingly, plasma of the reaction gas is generated in the region R. That is, in the gas supply process and the plasma supply process of the 1^{st} step, the atomic layer or the molecular layer adsorbed on the surface of the substrate W is nitrated by the plasma of the reaction gas generated by the plasma generating section 122.

Next, the film forming apparatus 100, in the second gas exhaust process of the 1^{st} step, exhausts the gas within the region R by the exhaust device 134 so that the region R is placed in a vacuum state. Next, the film forming apparatus 100, in the second purge gas supply process of the 1^{st} step, injects a purge gas supplied by the gas supply section 116 to the substrate W. Accordingly, Si excessively chemically adsorbed on the substrate W is removed. As described above, the whole process in the step is completed. Then, the film forming apparatus 100 sequentially performs 2^{nd} to p1^{th} steps which are the same as the 1^{st} step. The 1^{st} to p1^{th} steps are called a plasma ALD sequence.

In this manner, the film forming apparatus 100 repeatedly performs each step (the DCS gas supply, the first gas exhaust, the first purge gas supply, the gas supply, the plasma supply, the second gas exhaust, and the second purge gas supply) on the substrate W, p1 times. Accordingly, a silicon nitride film is formed on the substrate W to a target film thickness.

Next, the film forming apparatus 100 sequentially performs a (p1+1)^{th} step of a gas supply process, a plasma supply process, a second gas exhaust process, and a second purge gas supply process. As described above, impurities on the substrate W are removed, and then the process in the (p1+1)^{th} step is completed. The film forming apparatus 100 repeatedly performs the same step as the (p1+1)^{th} step until (p1+p2)^{th} step. Here, p2 is a natural number and refers to the number of repetitions of the same step as the (p1+1)^{th} step until the nitride film of a target film quality is formed through the film forming process by the film forming apparatus 100.

The gas supplied in the gas supply process in the (p1+1)^{th} to (p1+p2)^{th} steps is a modifier gas which is any one of N₂, NH₃, Ar, and H₂, or a mixed gas obtained by appropriately mixing these gases. The gas supplied in the second purge gas supply process of the (p1+1)^{th} step is an inert gas such as Ar. The (p1+1)^{th} to (p1+p2)^{th} steps are called a plasma post-treatment. A time T31 in which the film forming apparatus 100 performs the 1^{st} to p1^{th} steps, and a time T32 in which the film forming apparatus 100 performs the (p1+1)^{th} to (p1+p2)^{th} steps may be properly varied by the control of a control unit 160.

In the third exemplary embodiment, the same gas may be used for the reaction gas and the modifier gas, and the exhaust of the gas from the inside of the processing container may be omitted, thereby improving the processing efficiency.

### Effect of Third Exemplary Embodiment

According to the third exemplary embodiment, through a relatively simple configuration of the film forming apparatus 100, the film quality of a nitride film may be efficiently improved, and the film thickness of the nitride film may be secured. That is, it is possible to improve both the throughput of film forming and the film quality.

### Fourth Exemplary Embodiment

The fourth exemplary embodiment has the same as the third exemplary embodiment in configuration of a film forming apparatus. The fourth exemplary embodiment is different from the third exemplary embodiment in that in a film forming process, a DCS adsorption pre-treatment to be described later is performed prior to the DCS adsorption treatment to be described below. Hereinafter, a film forming process by a film forming apparatus according to the fourth exemplary embodiment will be described. The film forming apparatus according to the fourth exemplary embodiment is referred to as a film forming apparatus 100a.

### Details of Film Forming Process According to Fourth Exemplary Embodiment

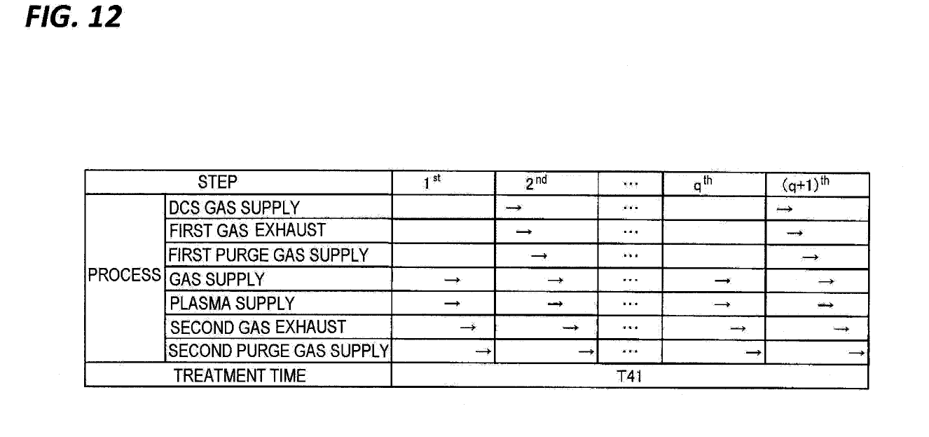

FIG. 12 is a view illustrating details of a film forming process according to the fourth exemplary embodiment. The pre-treatment of a film forming process in the fourth exemplary embodiment is the same as that in the third exemplary embodiment. As illustrated in FIG. 12, in a 1^{st} step, the film forming apparatus 100a sequentially performs respective processes of a gas supply, a plasma supply, a second gas exhaust, and a second purge gas supply in the same manner as in the (p1+1)^{th} step of the third exemplary embodiment. The gas supplied in the gas supply process of the 1^{st} step is a modifier gas which is the same as that of the third exemplary embodiment. The 1^{st} step is called a DCS adsorption pre-step in the same manner as in the second exemplary embodiment. The gas supplied in the gas supply process of the 1^{st} step is preferably a N₂ gas as a single gas or an Ar gas as a single gas.

Next, the film forming apparatus 100a performs the same step as the 1^{st} step in the third exemplary embodiment, as a 2^{nd} step. The 2^{nd} step is called a DCS adsorption step in the same manner as in the second exemplary embodiment. The film forming apparatus 100 performs the DCS adsorption pre-step and the DCS adsorption step which are the same as 1^{st} and 2^{nd} steps, until q^{th} to (q+1)^{th} steps. Here, q is a natural number, and refers to the number of repetitions of the DCS adsorption pre-step and the DCS adsorption step until the nitride film of a target film quality is formed through the film forming process by the film forming apparatus 100. A time T41 in which the film forming apparatus 100a performs 1^{st} to (q+1)^{th} steps may be properly varied by the control of the control unit 160.

### Effect of Fourth Exemplary Embodiment

According to the fourth exemplary embodiment, the film forming apparatus 100a may efficiently form a nitride film of high quality through a relatively simple configuration.

### Other Exemplary Embodiments

The first to fourth exemplary embodiments have been described above, but the first to fourth exemplary embodiments may be performed in a proper combination. On a substrate on which a film is formed and a plasma post-treatment is performed by the film forming apparatus 10 according to the first exemplary embodiment, film forming may be performed by the film forming apparatus 10a according to the second exemplary embodiment. Otherwise, on a substrate on which a film is formed and a plasma post-treatment is performed by the film forming apparatus 100 according to the third exemplary embodiment, film forming may be performed by the film forming apparatus 100a according to the fourth exemplary embodiment. Accordingly, it is possible to improve both the film quality of a nitride film and the throughput of film forming.

On a substrate on which a film is formed and a plasma post-treatment is performed by the film forming apparatus 10 according to the first exemplary embodiment, film forming may be performed by the film forming apparatus 10a according to the second exemplary embodiment, and then a film may be formed and a plasma post-treatment may be performed again by the film forming apparatus 10. Alternatively, on a substrate on which a film is formed and a plasma post-treatment is performed by the film forming apparatus 100 according to the third exemplary embodiment, film forming may be performed by the film forming apparatus 100a according to the fourth exemplary embodiment, and then a film may be formed and a plasma post-treatment may be performed again by the film forming apparatus 100. Accordingly, it is possible to improve both the film quality of a nitride film and the throughput of film forming.

On a substrate on which a film is formed by the film forming apparatus 10a according to the second exemplary embodiment, film forming may be performed and film quality may be modified by the film forming apparatus 10 according to the first exemplary embodiment, and then film forming may be performed again by the film forming apparatus 10a. Alternatively, on a substrate on which a film is formed by the film forming apparatus 100a according to the fourth exemplary embodiment, film forming may be performed and film quality may be modified by the film forming apparatus 100 according to the third exemplary embodiment, and then film forming may be performed again by the film forming apparatus 100a. Accordingly, it is possible to improve both the film quality of a nitride film and the throughput of film forming.

In the first to fourth exemplary embodiments and other exemplary embodiments, a nitride film is formed on a surface of a substrate by an ALD method, but the present disclosure is not limited thereto. The nitride film may be formed on the surface of the substrate by an MLD method.

For example, in the fourth exemplary embodiment, it is described, as an example, that the DCS adsorption pre-step and the DCS adsorption step are repeated. However, the present disclosure is not limited thereto. For example, without performing the DCS adsorption pre-step, the DCS adsorption step (which may be referred to as a third reaction step) may be repeated a predetermined number of times, and then a treatment which is the same as the DCS adsorption pre-step may be performed before the modifier gas is supplied. That is, the present disclosure may include, before the second reaction step, a third reaction step in which a gas including at least one of an argon gas and a nitrogen gas is supplied into the processing container to generate plasma of the supplied gas, and the plasma is reacted with the surface of the substrate. As a result, the number of processes may be reduced and a nitride film of high quality may be formed.

A control program of the film forming process described in each of the exemplary embodiments may be stored an optically or magnetically writable and readable recording medium, or a storage device by a semiconductor device. The storage medium is, for example, a DVD, a SD, a flash memory, or a Blu-ray disk. It is possible to cause a computer to acquire a control program from another computer that has read the control program from a storage device, and execute the acquired control program, via a computer network.

### Example 1

Hereinafter, Example 1 related to the above described third exemplary embodiment will be described. In Example 1, Test 1 performed by the film forming apparatus 100 according to the third exemplary embodiment will be described. In Test 1, when nitride films were formed on silicon wafer substrates by a plasma ALD sequence, and a plasma post-treatment was performed in the film forming apparatus 100 according to the third exemplary embodiment, test samples were evaluated. Accordingly, the improvement of film quality of the nitride films was verified. The film quality of the nitride films is evaluated based on, for example, film thickness, film thickness uniformity, film forming distribution as well as anti-oxidizing property.

(Concerning Condition of Executing Plasma ALD Sequence)

In Test 1, execution conditions of the plasma ALD sequence of forming the nitride films on the surfaces of the silicon wafers were as follows. As for the reaction gas, a mixed gas of NH₃/N₂/Ar was used. The pressure when forming the film was 5 Torr. The microwave power supplied when forming the film was 4 kW. The treatment time was 10 sec.

(Concerning Execution Condition of Plasma Post-Treatment)

In Test 1, the execution conditions of the plasma post-treatment performed on the nitride films were as follows. That is, as for the modifier gas, four patterns of gases (a mixed gas of NH₃/N₂/Ar, a mixed gas of NH₃/Ar, a mixed gas of N₂/Ar, and an Ar gas as a single gas) were used. As for the pressure at the plasma post-treatment, three patterns of pressures (1 Torr, 3 Torr, and 5 Torr) were employed. As for the microwave power supplied at the plasma post-treatment, three patterns of powers (2 kW, 3 kW, and 4 kW) were employed. As for the plasma post-treatment time, two patterns of time (5 min, and 10 min) were employed.

(Concerning Evaluation Method of Film Quality)

In Test 1, when test samples were etched by being immersed in DHF (0.5% hydrofluoric acid) for 30 sec and 150 sec (30 sec+120 sec), the etching rate was calculated for each test sample by dividing a thickness amount of the test sample by a thickness amount before the immersion. An index sample obtained by forming a thermal oxide film on the same substrate as that of the test sample was immersed in DHF, and the etching rate of the index sample was calculated. A wet etching rate ratio (WERR) obtained by dividing the etching rate of the test sample by the etching rate of the index sample was considered as an evaluation index.

A WERR when each test sample was immersed in DHF for 30 sec was referred to as WERR1, and a WERR when the test sample was immersed for 150 sec (30+120 sec) was referred to as WERR2. A sample obtained by forming a nitride film under the same conditions as those in the test sample without performing a plasma post-treatment was referred to as a comparative sample. In relation to both the test samples and the comparative samples, WERR1 and WERR2 were calculated and compared to each other so as to evaluate the modifying effects on the nitride film by the plasma post-treatment. A low WERR value indicates that the anti-etching property is good and the film quality is good.

The WERR was used as the evaluation index so as to suppress an evaluation error caused by an influence of a concentration of DHF as much as possible. The WERR1 is an index for evaluating a film quality on or near the surface of the nitride film of a sample. The WERR2 is an index for evaluating a film quality of the inside of the nitride film of a sample. At a relatively short term immersion, an area on or near the surface of a sample is etched, and at a long term immersion, the inside of the film of a sample is etched. Hereinafter, the DHF immersion is called a DHF treatment.

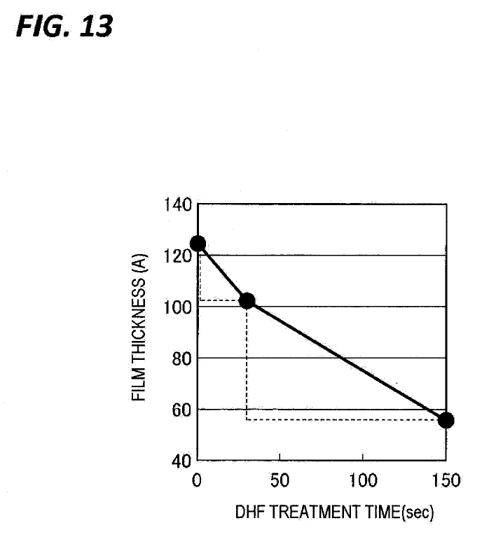

FIG. 13 is a view illustrating a relationship between the DHF treatment time and the film thickness. In FIG. 13, the DHF treatment time (sec) is represented on the horizontal axis and the film thickness (A (angstrom)) is represented on the vertical axis so as to illustrate the relationship between the DHF treatment time and the film thickness. As illustrated in FIG. 13, when the DHF treatment time was increased, the film thickness was decreased. More specifically, the slope of the straight line when the DHF treatment time ranges from 0 sec to about 30 sec is larger than the slope of straight line when the DHF treatment time ranges from about 30 sec to 150 sec.

This indicates that an area on or near the surface of the nitride film is more easily etched than the inside of the film, and the film quality of the area on or near the surface of the nitride film is inferior to the film quality of the inside of the film. Based on the knowledge from the results illustrated in FIG. 13, the film quality of the area on or near the surface of each nitride film was evaluated by the WERR (WERR1) when the DHF treatment time was 30 sec. The film quality of the inside of each nitride film was evaluated by the WERR (WERR2) when the DHF treatment time was 150 sec (30 sec+120 sec).

(Concerning Test Recipe)

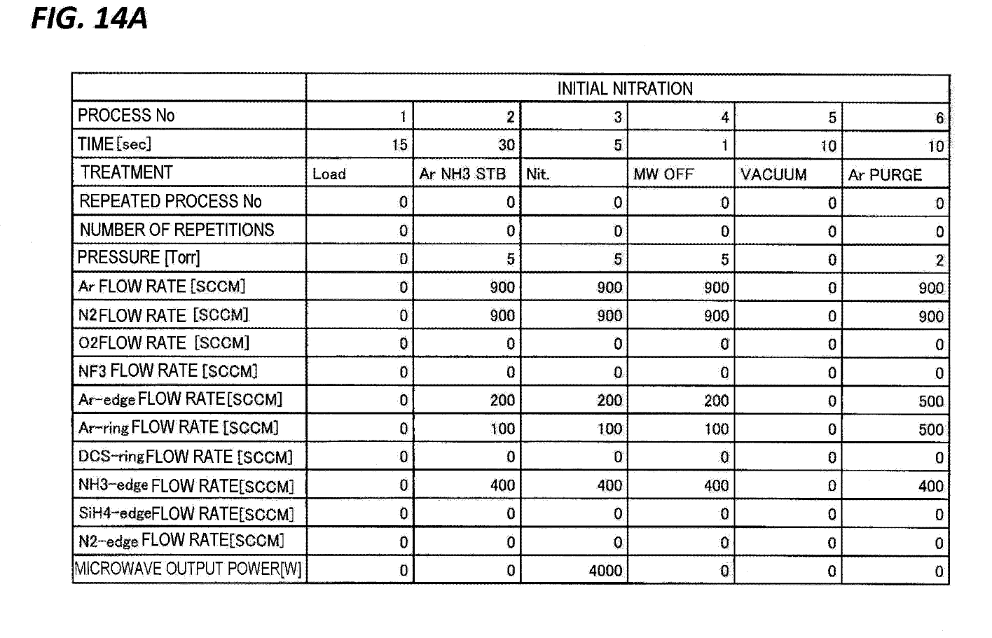

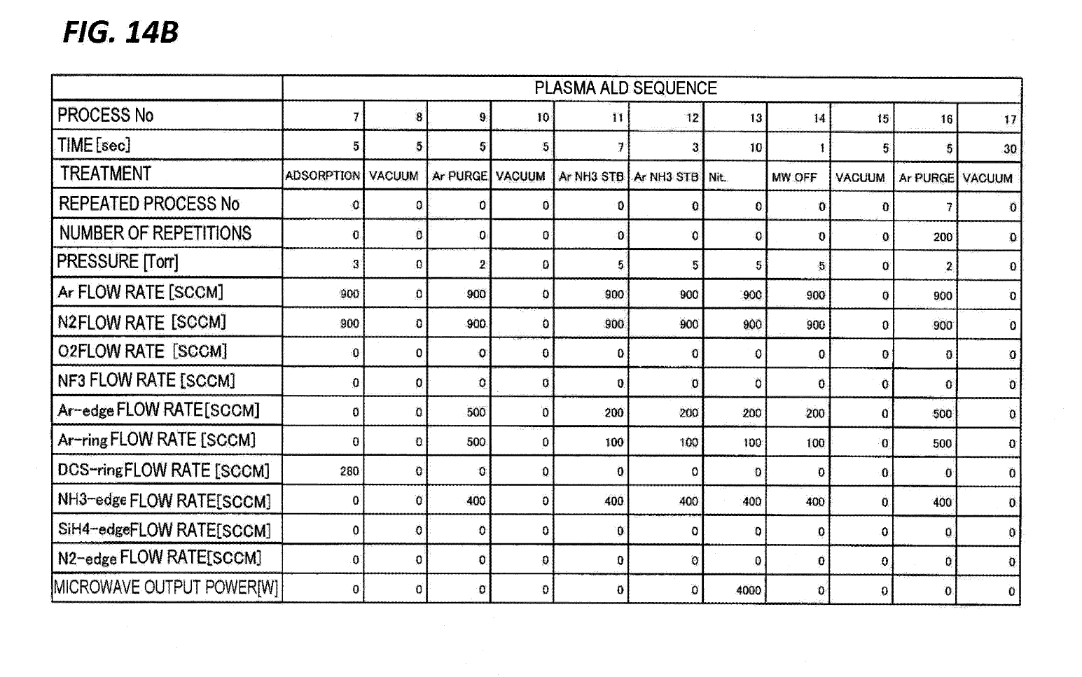

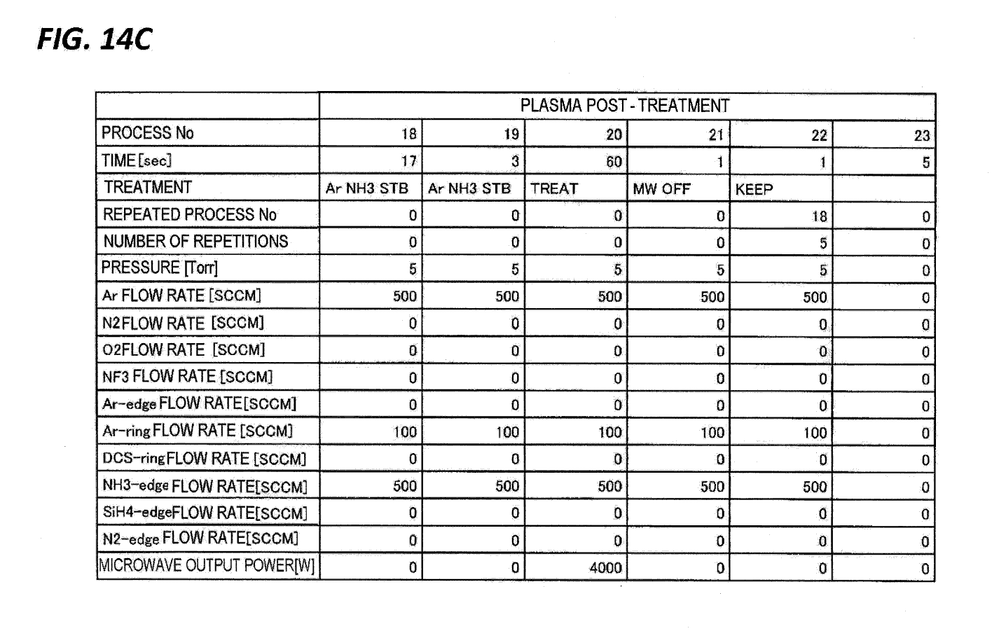

In Example 1, Test 1 was performed according to the test recipe illustrated in FIGS. 14A to 14C. As illustrated in FIG. 14A, as initial nitration, processes Nos. 1 to 6 were performed. As illustrated in FIG. 14B, as a plasma ALD sequence, processes Nos. 7 to 17 were performed. In the plasma ALD sequence, the processes Nos. 7 to 16 were repeatedly performed 200 times. As illustrated in FIG. 14C, as the plasma post-treatment, processes Nos. 18 to 23 were performed. In the plasma post-treatment, a series of processes Nos. 18 to 22 was repeatedly performed 5 times.

In FIGS. 14A to 14C, “Time” corresponding to each process number indicates a time for which a corresponding “Treatment” was performed. “Treatment” indicates a name of a performed treatment. “Load” is a loading treatment of a control program. “Ar NH₃ STB” is a stable supply treatment of Ar/NH₃. “STB” stands for stability. “Nit.” is a reaction gas supply treatment and a plasma supply treatment in the initial nitration and the plasma ALD sequence. “Nit.” stands for niditration.

“MW OFF” is a halting treatment of microwaves. “VACUUM” is a gas exhaust treatment. “Ar PURGE” is a purge gas supply treatment. “ADSORPTION” is a DCS adsorption treatment. “TREAT” is a treatment of supplying a modifier gas and plasma in the plasma post-treatment. “KEEP” is a gas supply keeping treatment performed after microwaves are halted in the plasma post-treatment.

In FIGS. 14A to 14C, “Pressure” corresponding to each process number is a pressure of the region R of the film forming apparatus 100. “Ar flow rate” is a flow rate of Ar supplied to the region R from the upper side through the gas supply ports 116a. “N₂ flow rate” is a flow rate of N₂ supplied to the region R from the upper side through the gas supply ports 116a. “O₂ flow rate” is a flow rate of O₂ (oxygen) supplied to the region R from the upper side through the gas supply ports 116a. “NF3 flow rate” is a flow rate of NF₃ (nitrogen trifluoride) supplied to the region R from the upper side through the gas supply ports 116a.

“Ar-edge flow rate” is a flow rate of Ar supplied to the region R from the lateral side through the gas supply ports 120a. “Ar-ring flow rate” is a flow rate of Ar injected to a substrate W through the ALD ring. “DCS-ring flow rate” is a flow rate of DCS injected to the substrate W through the ALD ring. “NH3-edge flow rate” is a flow rate of NH₃ supplied to the region R from the lateral side through the gas supply ports 120a. “SiH4-edge flow rate” is a flow rate of SiH₄ (monosilane) supplied to the region R from the lateral side through the gas supply ports 120a. “N2-edge flow rate” is a flow rate of N₂ supplied to the region R from the lateral side through the gas supply ports 120a. “Microwave output” is a power of microwaves supplied to the plasma generating section 122.

For example, FIG. 14A illustrates that in process No. 3, a plasma supply treatment was performed for 5 sec. Here, it is represented that the pressure of the region R was set to 5 torr, and Ar of 900 SCCM and N₂ of 900 SCCM were supplied to the region R from the upper side through the gas supply ports 116a. Also, Ar of 200 SCCM and NH₃ of 400 SCCM were supplied to the region R from the lateral side through the gas supply ports 120a. Also, Ar of 100 SCCM was injected to the substrate W through the ALD ring. Also, microwaves of 4000 W were supplied to the plasma generating section 122. According to FIG. 14A, each feeding position and component ratio of the supplied reaction gas and the supplied modifier gas may be understood. This is the same in FIGS. 14B and 14C.

(Relationship Between Pressure and Microwave Power in Plasma Post-Treatment)

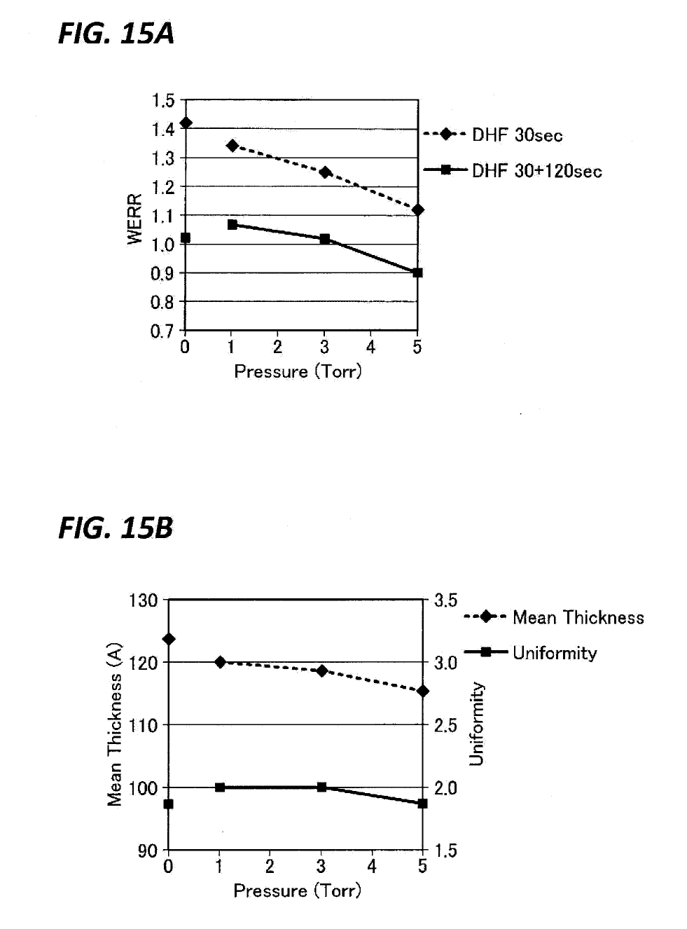

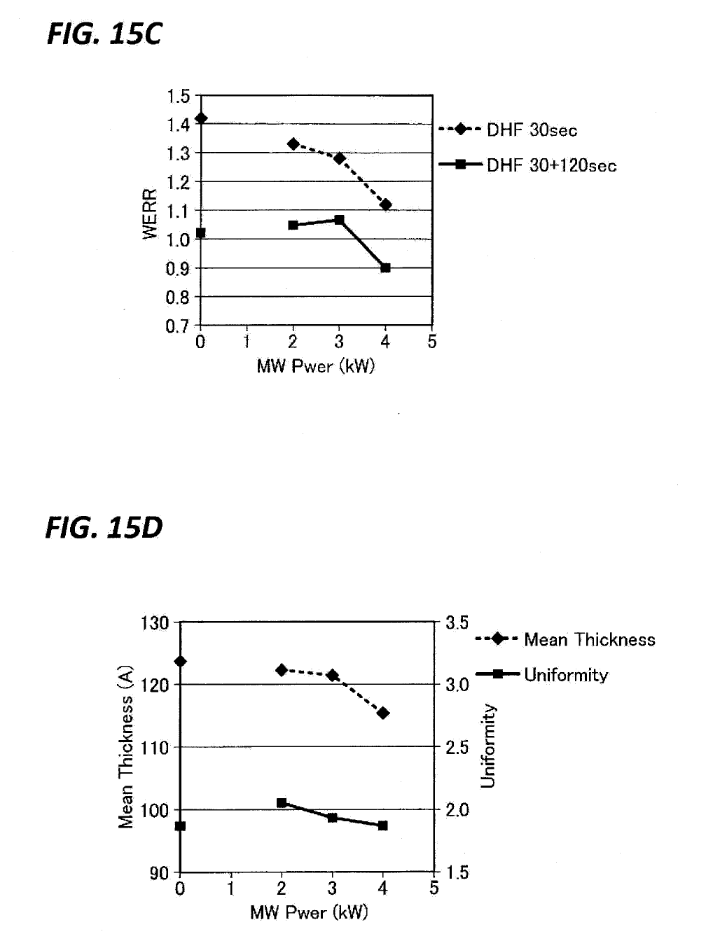

FIGS. 15A to 15D are views illustrating a relationship between a pressure and a microwave power in a plasma post-treatment. FIGS. 15A to 15D illustrate a case where p2 was 5, each step was performed for 60 sec, and a treatment time T32 was 300 sec (=60 sec×5) in the plasma post-treatment in (p1+1)^{th} to (p1+p2)^{th} steps illustrated in FIG. 11 in the third exemplary embodiment. According to FIGS. 15A to 15D, in the plasma post-treatment, an effect of improving film quality was increased as the pressure was increased and the microwave power was increased.

As illustrated in FIG. 15A, it can be found that in the plasma post-treatment, as the pressure is increased, the WERR is decreased, and thus a modifying effect of film quality of the nitride film is increased. In particular, an improvement effect of WERR1 which is the WERR of a test sample in a 30 sec DHF treatment is significant. WERR2 which is the WERR indicating the film quality of the inside of the nitride film in a 30+120 sec DHF treatment was degraded at 1 Torr, unchanged at 3 Torr, and improved at 5 Torr.

As illustrated in FIG. 15B, it can be found that at the pressures of 1 Torr and 3 Torr, Mean Thickness (mean film thickness) was decreased, and Uniformity (film thickness uniformity) was degraded. Also, it can be found that at Pressure of 5 Torr, both Mean Thickness and Uniformity were improved. That is, it can be found that in the film forming distribution, Uniformity was not degraded even by the plasma post-treatment. Uniformity is a percentage obtained by dividing a standard deviation of a film thickness distribution on the same substrate by an average value of distributed film thicknesses. A low value of Uniformity indicates that film thickness uniformity of the nitride film is high.

As illustrated in FIG. 15C, it was found that at MW Power (microwave power) of 2 kW and 3 kW, only WERR1 was improved, and at 4 kW, both the WERR1 and the WERR2 were improved. That is, at MW power of 2 kW and 3 kW, the modifying effect of a film quality was confirmed only on or near the surface of the nitride film, but at 4 kW, the modifying effect of film quality was confirmed at the inside of the nitride film as well as on or near the surface.

As illustrated in FIG. 15D, it can be found that at MW Power of 2 kW and 3 kW, Mean Thickness was decreased, and Uniformity was degraded. Also, it can be found that at MW Power of 4 kW, Mean Thickness was decreased and Uniformity was improved.

When the plasma post-treatment is performed, a film thickness of a nitride film is decreased as compared to a case where the plasma post-treatment is not performed. It is believed that this is resulted from the fact that the nitride film is shrunk and densified by a heat input or a modifying reaction due to plasma. A decrease of the film thickness indicates a reduction of throughput in the film forming process, but is significant with respect to the improvement of film quality.

(Concerning Relationship Between Modifier Gas and Plasma Post-Treatment Time)

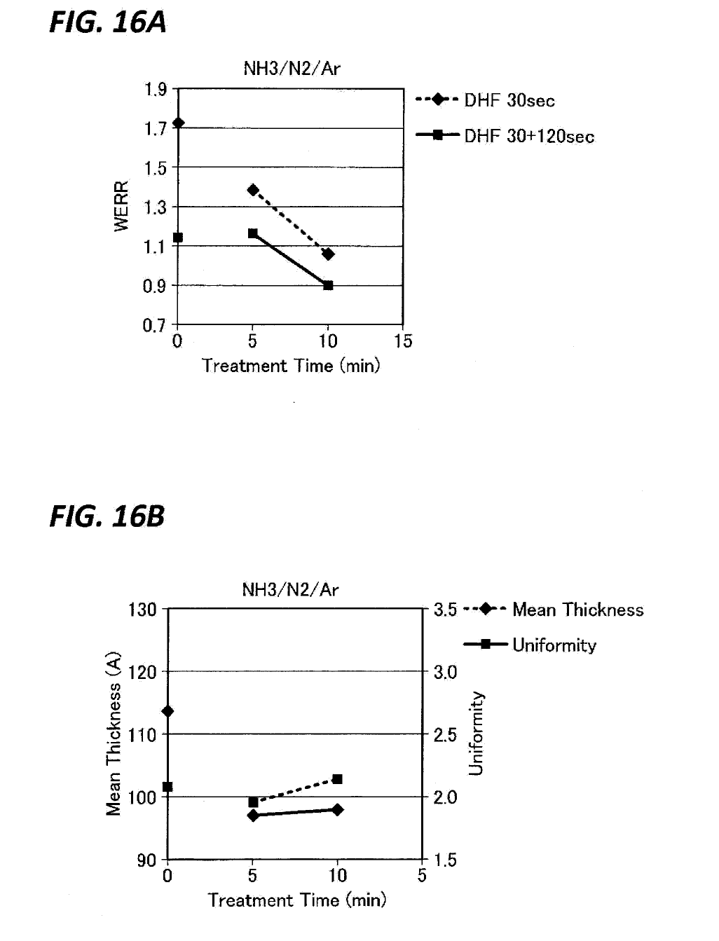

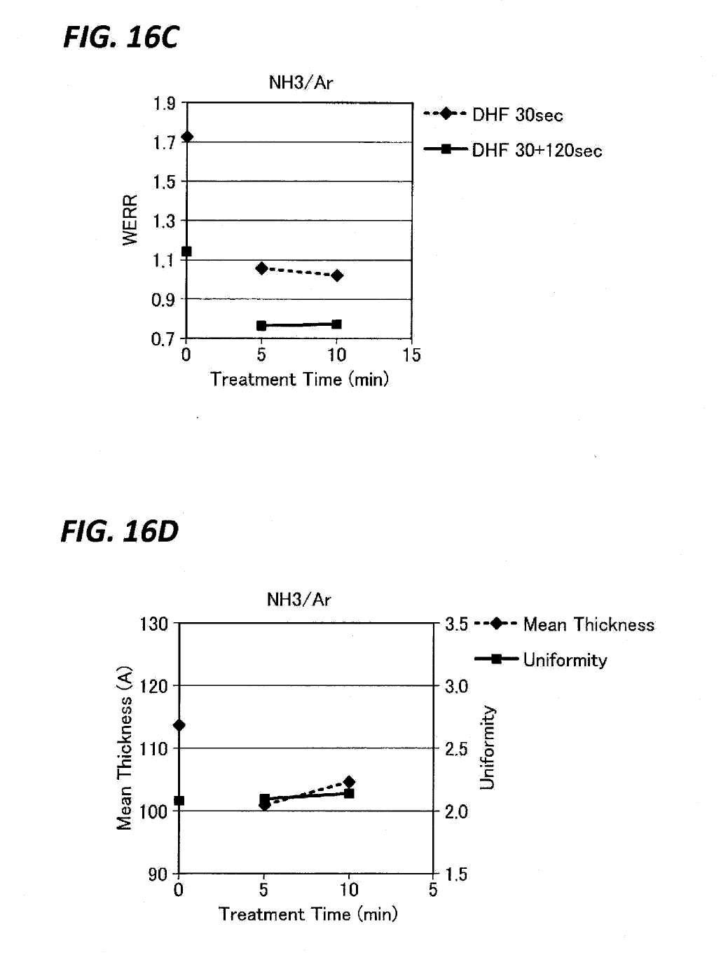

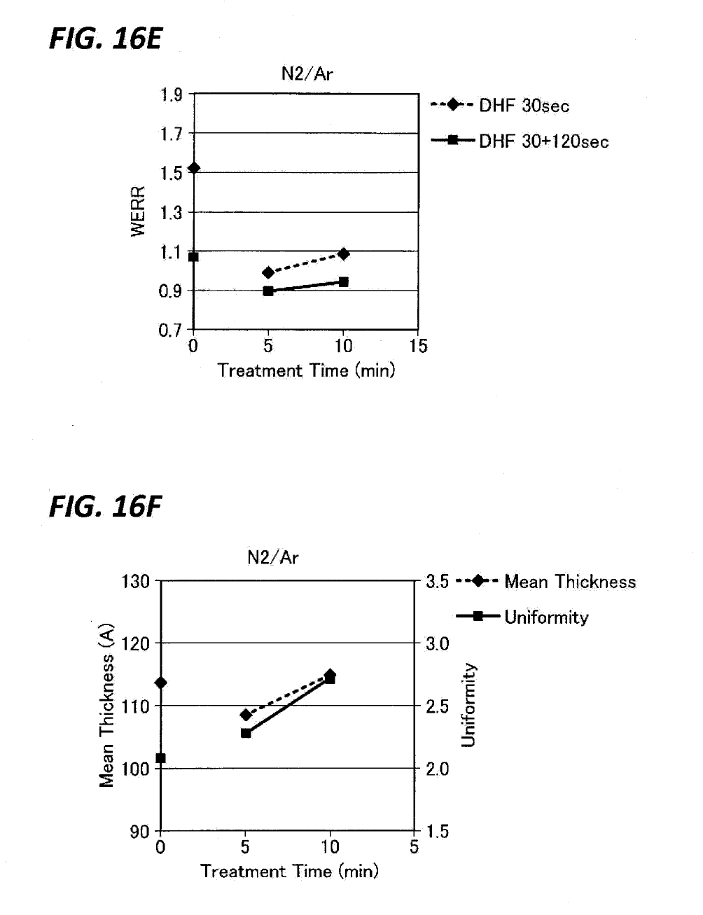

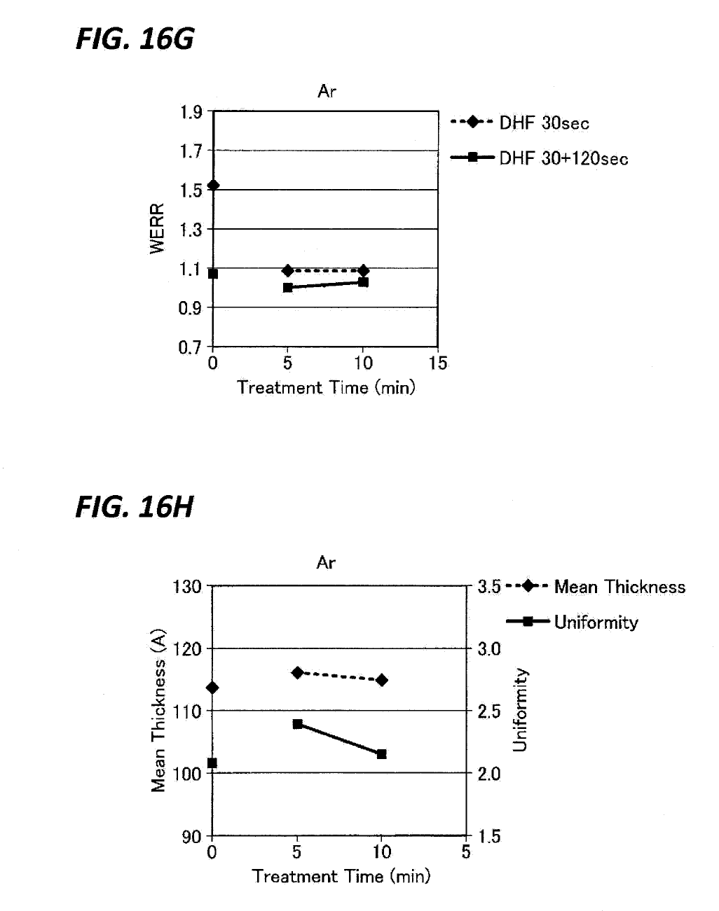

FIGS. 16A to 16H are views illustrating a relationship between a modifier gas and a plasma post-treatment time. FIGS. 16A to 16H illustrate a case where the plasma post-treatment time T32 illustrated in FIG. 11 in the third exemplary embodiment was set to 5 mm and 10 min. While using this condition as the plasma post-treatment condition and varying the modifier gases, WERR, Mean Thickness and Uniformity were compared to one another.

As illustrated in FIGS. 16A, 16C, 16E, and 16G, with respect to WERR, it was found that there is a difference in modifying effect between a modifier gas including NH₃, and a modifier gas not including NH₃. WERR1 was improved by any modifier gas of NH₃/N₂/Ar, NH₃/Ar, N₂/Ar, and Ar. That is, it was found that the area on or near the surface of the nitride film was improved by any modifier gas.

In the modifier gas of NH₃/N₂/Ar, the improvement of WERR2 was not always observed. That is, in the modifier gas of NH₃/N₂/Ar, the improvement of film quality of the inside of the nitride film was not observed when the plasma post-treatment time was 5 min, but was observed when the plasma post-treatment time was 10 min. In the modifier gas of each of NH₃/Ar, N₂/Ar, and Ar, the modifying effect in the inside of the film was confirmed although there is a difference in the effect.

In particular, when the modifier gas of NH₃/Ar was used, the effect of film quality improvement of the nitride film was high. Even when the plasma post-treatment time was 5 min, WERR1 was significantly improved from 1.72 to 1.05, and WERR2 was significantly improved from 1.14 to 0.75, as compared to a comparative sample obtained without the plasma post-treatment.

As illustrated in FIGS. 16B, 16D, 16F, and 16H, Mean Thickness was decreased in any modifier gas. Uniformity was unchanged or improved in the modifier gas of NH₃/N₂/Ar and NH₃/Ar, although the level was varied depending on Treatment Time.

(Modifying Depth of Nitride Film by Plasma Post-Treatment)

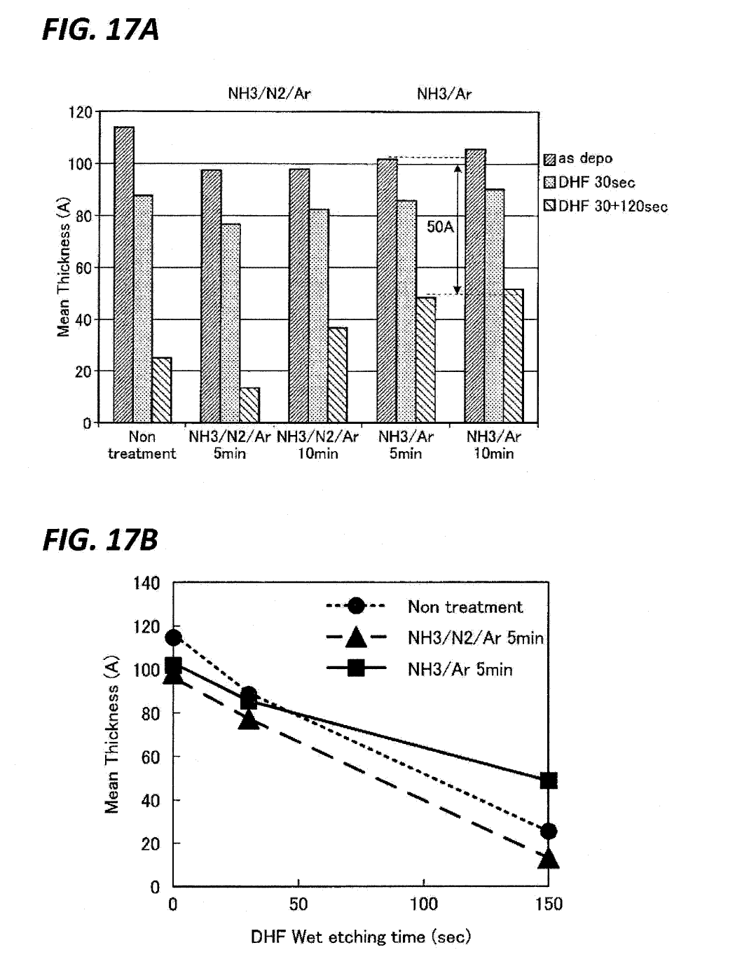

FIGS. 17A and 17B are views illustrating the modifying depth of a nitride film by a plasma post-treatment. Hereinafter, a test sample obtained by performing a plasma post-treatment by a mixed gas of NH₃/N₂/Ar for 5 min is referred to as a first test sample. A test sample obtained by performing a plasma post-treatment by a mixed gas of NH₃/N₂/Ar for 10 min is referred to as a second test sample. A test sample obtained by performing a plasma post-treatment by a mixed gas of NH₃/Ar for 5 min is referred to as a third test sample. A test sample obtained by performing a plasma post-treatment by a mixed gas of NH₃/Ar for 10 min is referred to as a fourth test sample. A sample obtained without performing a plasma post-treatment is referred to as a comparative sample.

On five samples, that is, the first to fourth test samples and the comparative sample obtained without performing the plasma post-treatment, a DHF treatment was performed. On each of the comparative sample, and the first to fourth test samples, Mean Thickness was measured before the DHF treatment (as depo), after the DHF treatment for 30 sec, and after the DHF treatment for 150 sec (=30 sec+120 sec).

FIG. 17A is a view illustrating measurement results of Mean Thickness. On the third and fourth test samples obtained by the plasma post-treatment using a mixed gas of NH₃/Ar exhibiting the highest modifying effect of a nitride film, a 5 min or 10 min DHF treatment was performed. As a result, as illustrated in FIG. 17A, Mean Thickness was decreased by about 50 A in both test samples.

As illustrated in FIG. 17B, when the DHF treatment was performed on the comparative sample and the first and third test samples, the reduction rate of Mean Thickness according to the DHF treatment time was minimized in the third test sample after about 50 sec. The reduction rate of Mean Thickness according to the DHF treatment time corresponds to a slope of straight line in FIG. 17B. The slope of straight line is a wet etching rate (A/sec). A small slope of straight line indicates that the wet etching rate is low, and the film quality is good.

As illustrated in FIG. 17B, it can be found that in the third test sample obtained by performing the plasma post-treatment by a modifier gas of NH₃/Ar, the film quality was improved. Also, as illustrated in FIG. 17B, the wet etching rate of the first test sample around 150 sec is smaller than that of the comparative sample obtained without performing the plasma post-treatment. A residual film at that time was 5 nm. An as-depo film thickness of the first test sample was 10 nm.

That is, according to FIGS. 17A and 17B, it can be found that a large amount of film remains when wet etching is performed up to about 5 nm from the surface of the nitride film. Accordingly, when radicals of a modifier gas act on the modification of the nitride film, the penetration depth of the radicals due to plasma irradiation, that is, the modifying depth of the nitride film is considered to be up to the inside of the film, that is, up to about 5 nm from the surface.

(Relationship Between Waveform Separation of Si 2p 3/2 Spectrum and TOA)

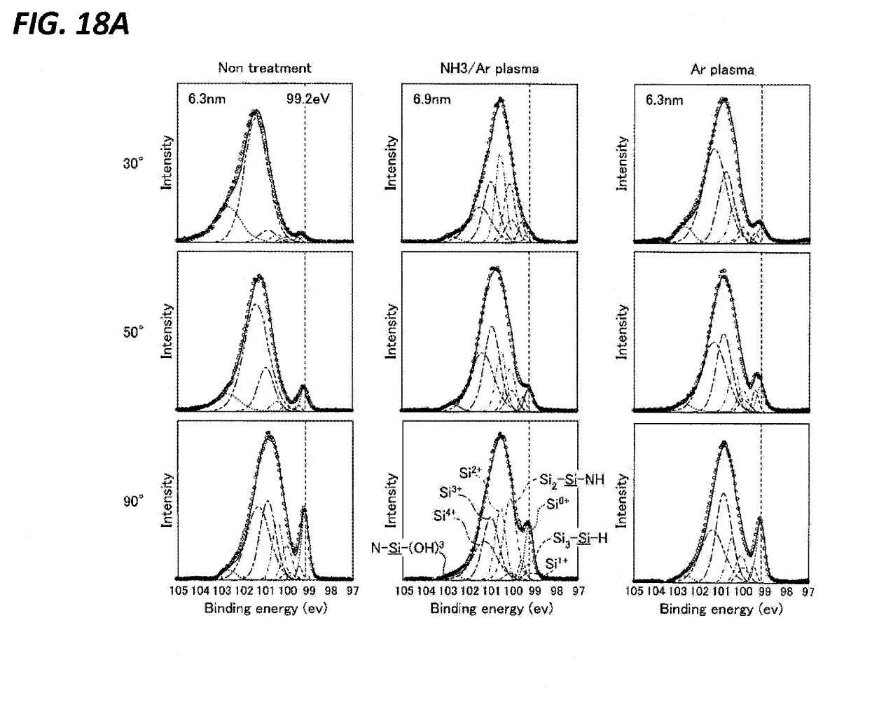

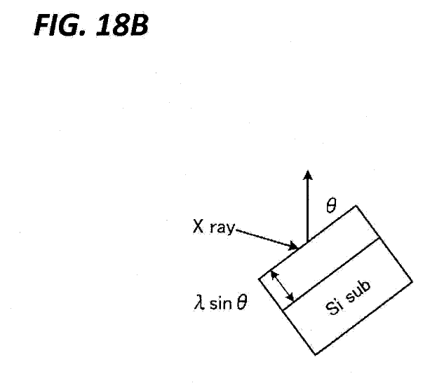

FIG. 18A is a view illustrating a relationship between a waveform separation result of Si 2p 3/2 spectrum and a TOA. Vertically three graphs in the left column of FIG. 18A correspond to a comparative sample obtained without performing a plasma post-treatment. Vertically three graphs in the middle column of FIG. 18A correspond to a test sample obtained by a NH₃/Ar plasma post-treatment. Vertically three graphs in the right column of FIG. 18A correspond to a test sample obtained by an Ar plasma treatment.

In the waveform separation illustrated in FIG. 18A, peak separation was performed by setting a peak shift amount of spin 1/2 and 3/2 to 0.06 eV, and a peak intensity ratio to 1:2, and a signal of spin 1/2 was removed from Si 2p spectrum. The peak positions were aligned to the signal peak 99.2 eV of a silicon substrate.

The angles of 30°, 50° and 90° illustrated at the left side of FIG. 18A correspond to θ illustrated in FIG. 18B. That is, θ illustrated in FIG. 18B is a take-off angle (TOA) of photoelectrons which escape from a nitride film when X rays are irradiated to the nitride film by using an angle-resolved XPS (photoelectron spectroscopy). A (nm) illustrated in FIG. 18B is an attenuation length of photoelectrons. That is, λ×sin θ (λ×sign value of θ) is an escape depth by which photoelectrons are escapable by a photoelectric effect caused by X-ray irradiation.

A symbol “Si³⁺” in the graph of the waveform separation result as illustrated in FIG. 18A represents a bonding state where three N atoms are bonded to one Si atom, around a focused Si atom. When surface sensitivity measurement is performed by reducing TOA, a reduction of signal intensity can be confirmed from the Si substrate. When TOA is reduced, the signal intensity of oxidation is increased. In this respect, it is believed that the test samples have been surface-oxidized by atmospheric exposure.

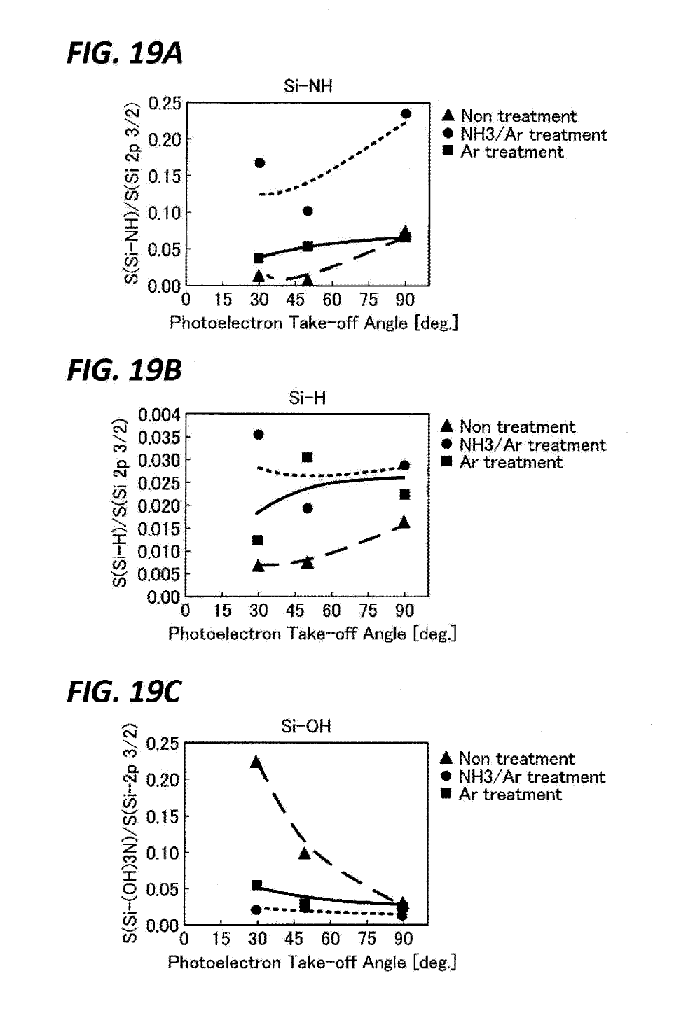

In the test sample obtained by NH₃/Ar plasma, a signal intensity of Si—NH bonds is stronger than other samples. In order to evaluate the ratio of the bonding state within the film, each separated peak area was standardized by a peak area of Si 2p 3/2 spectrum, and the results are illustrated in FIGS. 19A, 19B and 19C. The peak area refers to an area of a peak signal of Si 2p 3/2 spectrum of a material. The peak area ratio refers to a ratio of a peak area of each chemical bonding state with respect to the total area of a peak signal of Si 2p 3/2 spectrum of a compound.

(Modifying Effect of Nitride Film by Plasma Post-Treatment)

FIG. 19A is a view illustrating a relationship between a peak area of Si 2p 3/2 spectrum of Si—NH and a TOA in Example 1. FIG. 19B is a view illustrating a relationship between a peak area of Si 2p 3/2 spectrum of Si—H and a TOA in Example 1. FIG. 19C is a view illustrating a relationship between a peak area of Si 2p 3/2 spectrum of Si—OH and a TOA in Example 1.

As illustrated in FIG. 19A, the Si—NH bonds in NH₃/Ar plasma were less dependent on the TOA and have a larger peak area ratio as compared to other conditions. This indicates an increase of Si—NH bonds within the film.

When the plasma post-treatment was performed, Si—H bonds exhibited a tendency of being increased. However, as illustrated in FIG. 19B, since the peak area of Si—H with respect to the total peak area is small, a change amount of the total peak area according to an increase of the peak area of Si—H is small.

Meanwhile, as illustrated in FIG. 19C, there was a significant difference in the Si—OH bonds between a case where a plasma post-treatment was performed and a case where no plasma post-treatment was performed. Without the plasma post-treatment, as the TOA was decreased, the Si—OH intensity, that is, a surface oxidation amount, was increased. With the plasma post-treatment, the dependency of the peak area of the Si—OH bonds to the TOA is low. Accordingly, it is believed that the surface oxidation was suppressed by the plasma post-treatment. WERR of an oxide film is not better than that of the nitride film.

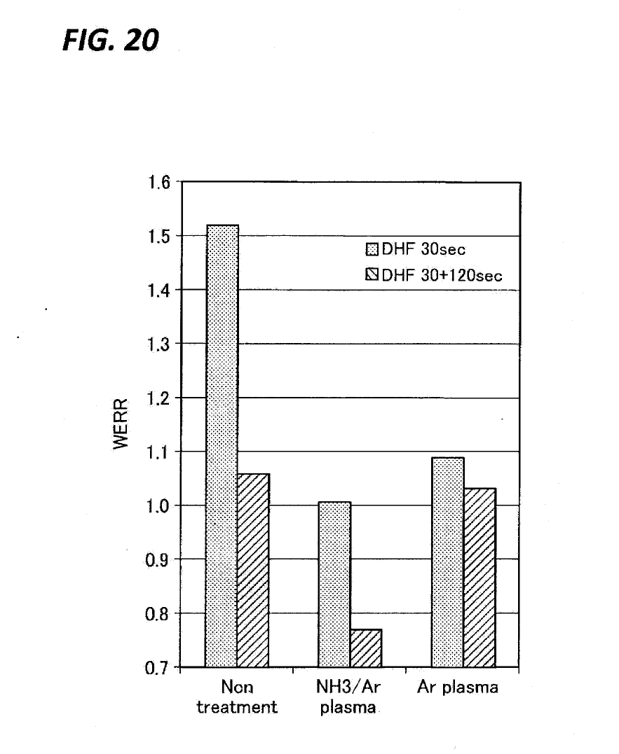

FIG. 20 is a view illustrating a change of a WERR by a plasma post-treatment. As illustrated in FIG. 20, it was found that surface film quality of a nitride film was improved by the plasma post-treatment. It is assumed that the improvement of the surface film quality of the nitride film was caused by the increase of NH bonds within the film. That is, it is thought that dangling bonds within the film were terminated by the supply of NH radicals through the plasma post-treatment, and an oxidation reaction between oxidation components in atmosphere with the dangling bonds was suppressed during atmospheric exposure. According to FIG. 20, it can be found that the NH₃/Ar plasma post-treatment improves the film quality at the inside of the nitride film as well as on the surface of the nitride film.

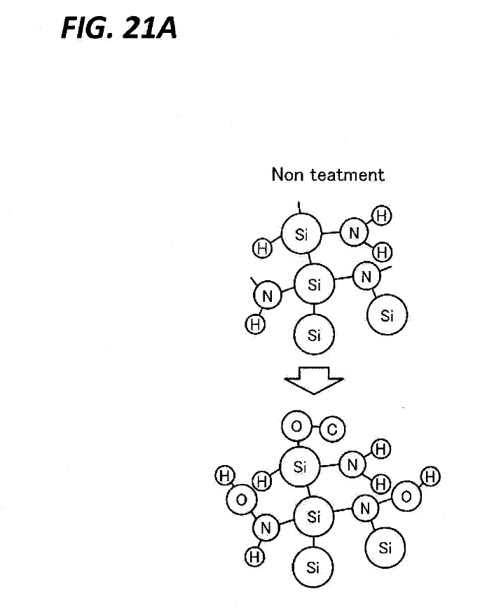

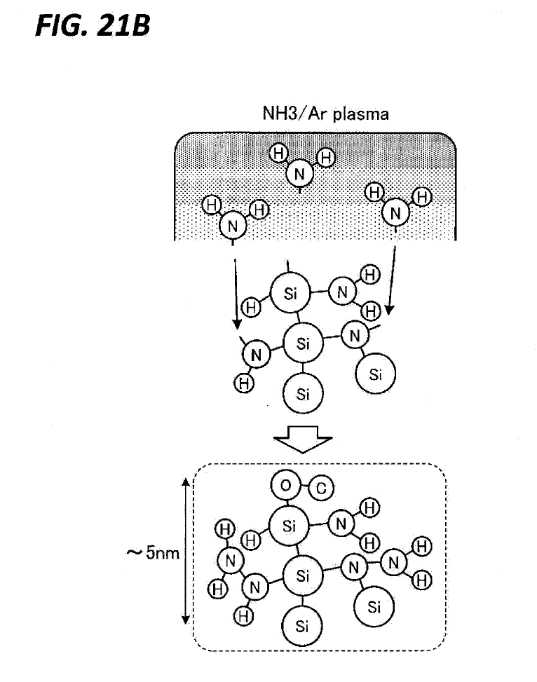

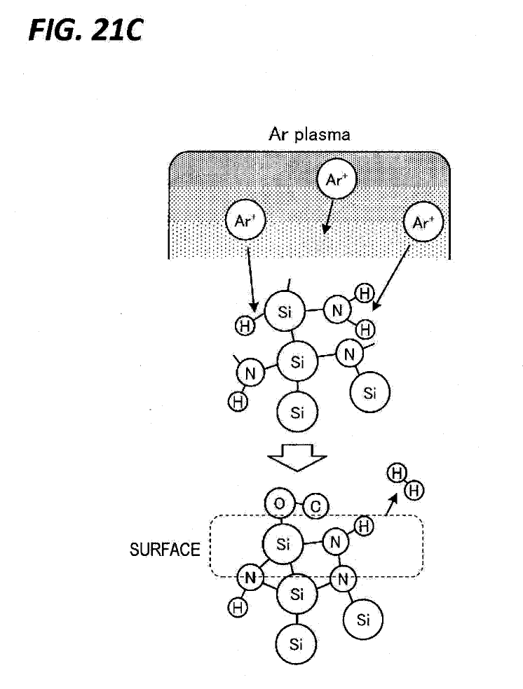

FIG. 21A is a view illustrating an outline in which, when there is no plasma post-treatment, dangling bonds of a nitride film are bonded to oxidation components in the atmosphere, thereby oxidizing the nitride film. FIG. 21B is a view illustrating an outline in which, when there is a NH₃/Ar plasma post-treatment, dangling bonds of N atoms within a nitride film are terminated. As illustrated in FIG. 21B, it is believed that the dangling bonds (DBs) of N atoms are terminated by radicals of NH₃, and thus the dangling bonds of the N atoms of a nitride film are reduced, thereby suppressing the bonds between the dangling bonds and oxidation components in the atmosphere. It is believed that the modifying effect of the nitride film by the NH₃/Ar plasma post-treatment ranges up to about 5 nm inside the film, and thus the DB termination by NH radicals ranges up to a depth of about is 5 nm from the film surface of the nitride film.

FIG. 21C is a view illustrating an outline in which, when there is an Ar plasma post-treatment, dangling bonds of N atoms are terminated. As illustrated in FIG. 21C, it is believed that H atoms bonded to Si atoms within a nitride film collide with Ar ions, and thus, bonds between H atoms and Si atoms are terminated. Then, it is believed that dangling bonds of N atoms are bonded to Si atoms, and thus the dangling bonds of the N atoms of a nitride film are reduced, thereby suppressing the bonds between the dangling bonds and oxidation components in the atmosphere. It is believed that the modifying effect of the nitride film by the Ar plasma post-treatment is confirmed only on the film surface, and thus DB bonds caused by ion collision occur on the film surface of the nitride film.

(Relationship between Plasma Supply Time of Plasma ALD Sequence and Effect of Plasma Post-Treatment)

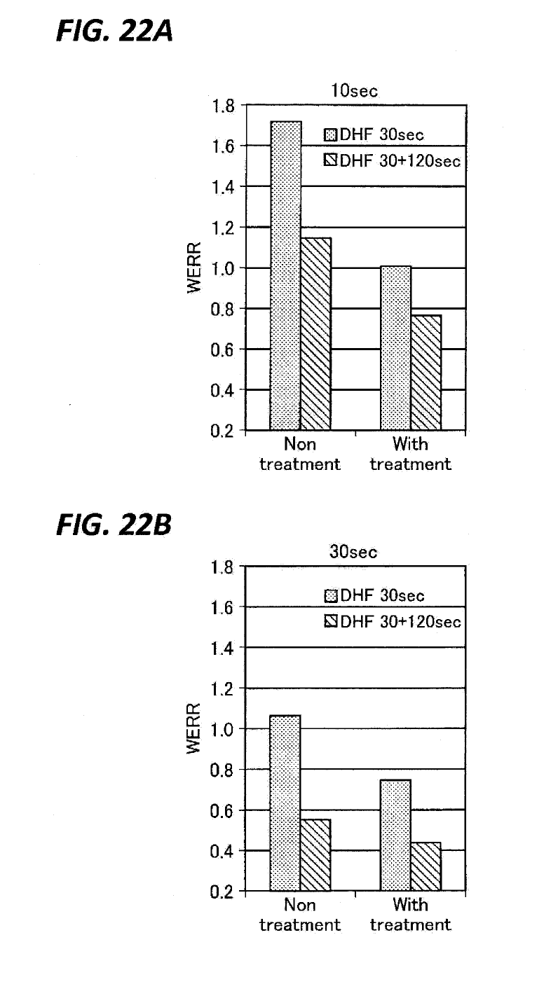

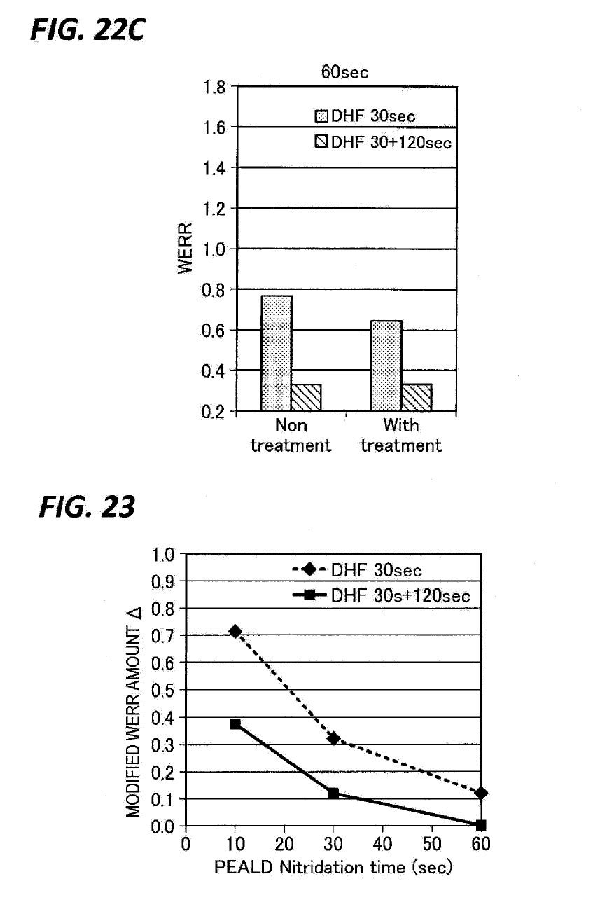

FIGS. 22A to 22C, and FIG. 23 are views illustrating a relationship between a plasma supply time in a plasma ALD sequence, that is, in forming a nitride film, and an effect of a plasma post-treatment. The plasma post-treatment performed on test samples in FIGS. 22A to 22C, and FIG. 23 was executed under conditions of a pressure of 5 Torr, a microwave power of 4 kW, and an execution time of 5 min. Among the samples formed with nitride films under the same conditions, a sample obtained without performing the plasma post-treatment was used as a comparative sample, and the other samples obtained by the plasma post-treatment were used as test samples.

FIG. 22A is a view illustrating changes of WERR1 and WERR2 in each of a comparative sample and a test sample when a plasma supply time in a plasma ALD sequence was 10 sec. FIG. 22B is a view illustrating changes of WERR1 and WERR2 in each of a comparative sample and a test sample when the plasma supply time in forming a nitride film was 30 sec. FIG. 22C is a view illustrating changes of WERR1 and WERR2 in each of a comparative sample and a test sample when a plasma supply time in forming a nitride film was 60 sec.

As illustrated in FIGS. 22A to 22C, WERR1 and WERR2 were improved when the plasma supply time is any of 10 sec, 30 sec, and 60 sec in the plasma ALD sequence. As illustrated in FIGS. 22A to 22C, when a sample with a smaller WERR value, i.e. a better film quality exhibited a lower effect of film quality improvement by the plasma post-treatment.

FIG. 23 is a view illustrating a plasma supply time in a plasma ALD sequence, and changes of WERR1 and WERR2. As illustrated in FIG. 23, when the plasma supply time in the plasma ALD sequence was increased, change amounts of WERR1 and WERR2 by the plasma post-treatment were reduced. That is, when the plasma supply time in film forming by the plasma ALD sequence was shorter, change amounts of WERR1 and WERR2 by the plasma post-treatment were larger. Since the change amount of WERR1 is larger than that of WERR2 regardless of the plasma supply time, it may be said that the effect of film quality improvement by the plasma post-treatment was large on or near the surface of the nitride film as compared to at the inside of the nitride film.

Accordingly, it may be said that a nitride film of good film quality may be formed when the nitride film is formed with a relatively thin film thickness by a short treatment time of a plasma ALD sequence and a film quality improving treatment by a plasma post-treatment is repeated. Accordingly, it may be said that even if the total execution time of the film forming process is shortened, a good nitride film may be formed and a throughput of the whole film forming process may be improved.

### Example 2

Hereinafter, Example 2 related to one of the above-described exemplary embodiments will be described. In Example 2, Test 2 performed by the film forming apparatus 100a according to the fourth exemplary embodiment will be described. In Test 2, in the film forming apparatus 100a according to the fourth exemplary embodiment, plasma of a modifier gas was supplied before a nitride film was formed on a substrate of a silicon wafer by a plasma ALD method. Then, a test sample obtained through the film forming process was evaluated to verify the modification of the nitride film. Unless otherwise specified, execution conditions of each treatment are the same as those in Example 1.

(Concerning Execution Conditions of Plasma ALD Sequence)

In Test 2, the execution conditions of the plasma ALD sequence of forming the nitride film on the surface of the silicon wafer were as follows. As for a modifier gas, a mixed gas of NH₃/N₂/Ar was used. The pressure when performing the DCS adsorption treatment was 5 Torr. The microwave power supplied at DCS adsorption treatment was 4 kW. The treatment time in the plasma ALD sequence was 10 sec.

(Concerning Execution Conditions of DCS Adsorption Pre-Treatment)

In Test 2, the execution conditions of a DCS adsorption pre-treatment included in the plasma ALD sequence were as follows. That is, as for the modifier gas, two patterns of gases (N₂ gas as a single gas or Ar gas as a single gas) were used. As for the pressure at the DCS adsorption pre-treatment, 5 Torr was employed. As for the power of microwaves supplied at the DCS adsorption pre-treatment, 4 kW was employed. As for the treatment time, two patterns of time (5 sec) were employed. As for the flow rate of the modifier gas from the ALD ring, three patterns of 100, 300, and 500 SCCM were employed. As for the total flow rate of the modifier gas with respect to the flow rate of the modifier gas from the ALD ring, 500, 1000, or 1500 SCCM was employed.

(Concerning Test Recipe)

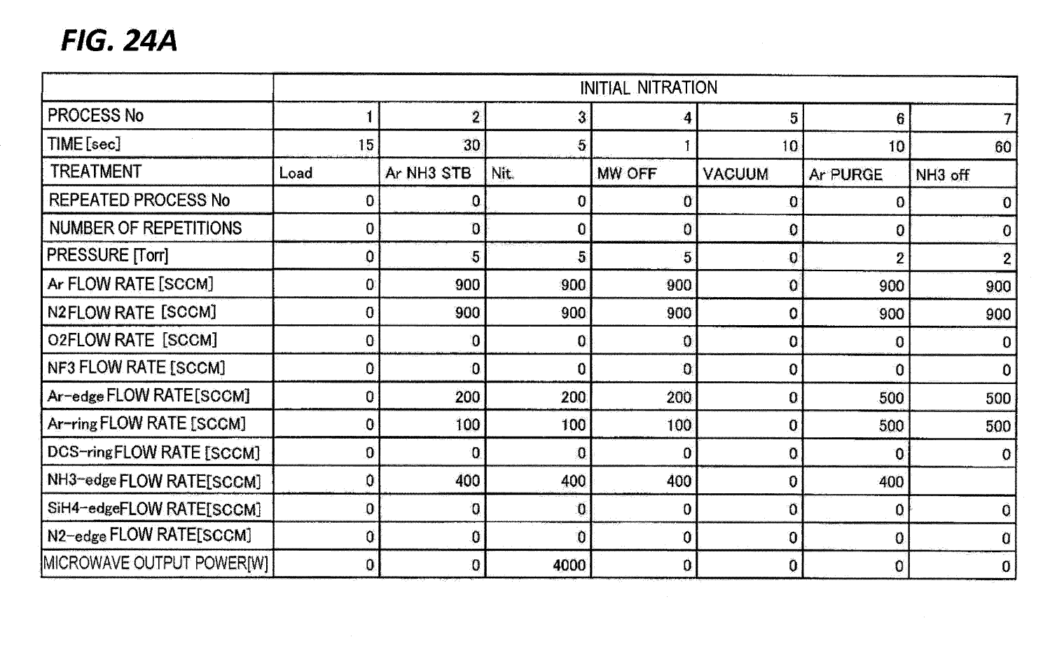

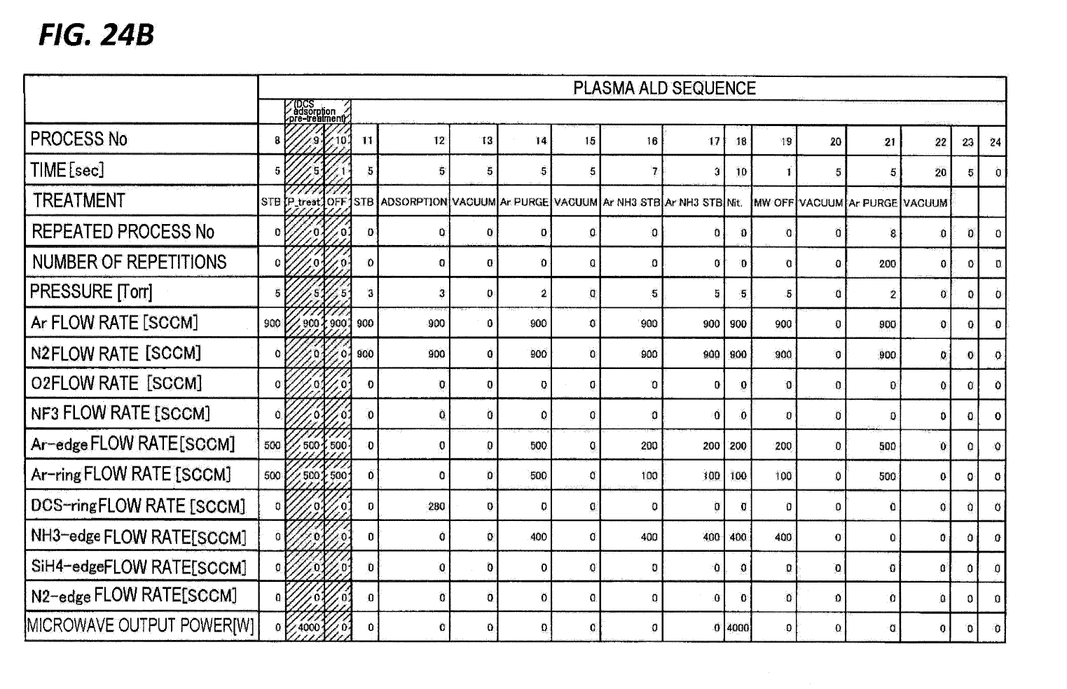

In Example 2, Test was performed according to the test recipe illustrated in FIGS. 24A and 24B. As illustrated in FIG. 24A, as the initial nitration, processes Nos. 1 to 7 were performed. As illustrated in FIG. 24B, as the plasma ALD sequence, processes Nos. 8 to 24 were performed. In the plasma ALD sequence in Example 2, processes Nos. 9 and 10 correspond to the DCS adsorption pre-treatment. In the plasma ALD sequence in Example 2, processes Nos. 11 to 21 correspond to the DCS adsorption treatment. In Example 2, processes Nos. 8 to 21 were repeatedly performed 200 times.

(Comparison between Ar Plasma and N₂ Plasma in DCS Adsorption Pre-Treatment)

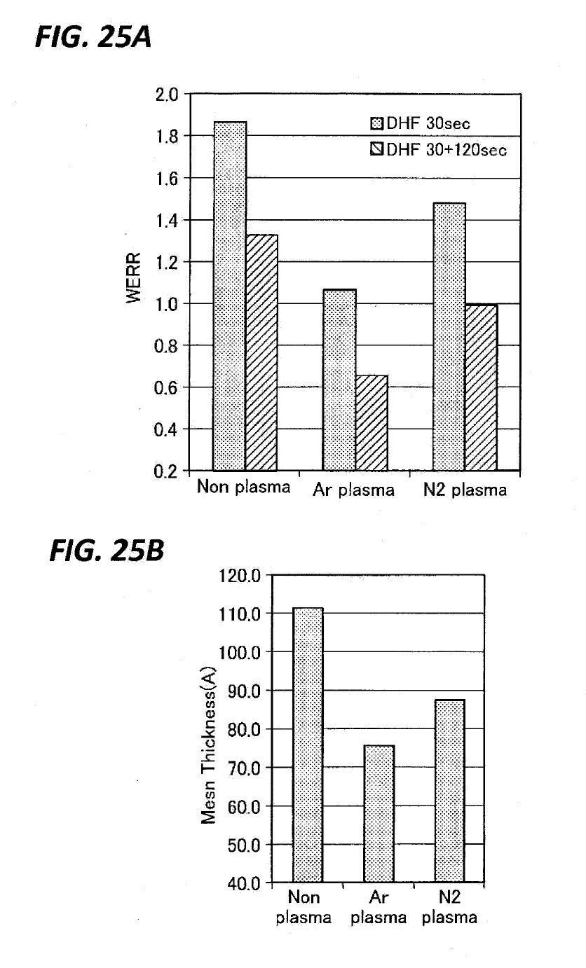

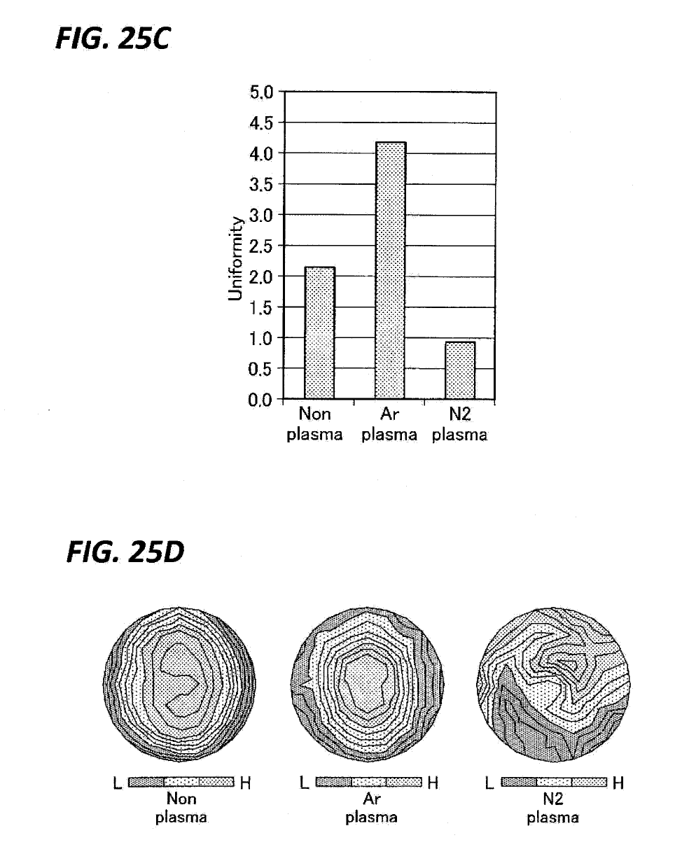

FIGS. 25A to 25D are views illustrating a comparison between Ar plasma and N₂ plasma in the DCS adsorption pre-treatment. As illustrated in FIG. 25A, as compared to the DCS adsorption pre-treatment, WERR1 and WERR2 were improved in both the Ar plasma DCS adsorption pre-treatment and the N₂ plasma DCS adsorption pre-treatment. In particular, as compared to in the N₂ plasma DCS adsorption pre-treatment, WERR1 and WERR2 were more greatly improved in the Ar plasma DCS adsorption pre-treatment.

As illustrated in FIG. 25B, as compared to that in the DCS adsorption pre-treatment, the film thickness average was reduced in both the Ar plasma DCS adsorption pre-treatment and the N₂ plasma DCS adsorption pre-treatment. In particular, as compared to that in the N₂ plasma DCS adsorption pre-treatment, the film thickness average was more greatly reduced in the Ar plasma DCS adsorption pre-treatment.

As illustrated in FIGS. 25C and 25D, as compared to those in the DCS adsorption pre-treatment, the film thickness uniformity in the Ar plasma DCS adsorption pre-treatment was degraded, but the film thickness uniformity in the N₂ plasma DCS adsorption pre-treatment was improved. FIG. 25D is a view illustrating a film thickness distribution by contour lines. In legend of hatching in FIG. 25D, the left side indicates a low film thickness and the left side indicates a high film thickness when FIG. 25D is viewed from the front side.

That is, in relation to the modification of film quality, the Ar plasma DCS adsorption pre-treatment was more excellent than the N₂ plasma DCS adsorption pre-treatment. Also, in relation to the film thickness uniformity, the N₂ plasma DCS adsorption pre-treatment was more excellent than the Ar plasma DCS adsorption pre-treatment.

(Waveform Separation of Si 2p 3/2 Spectrum)

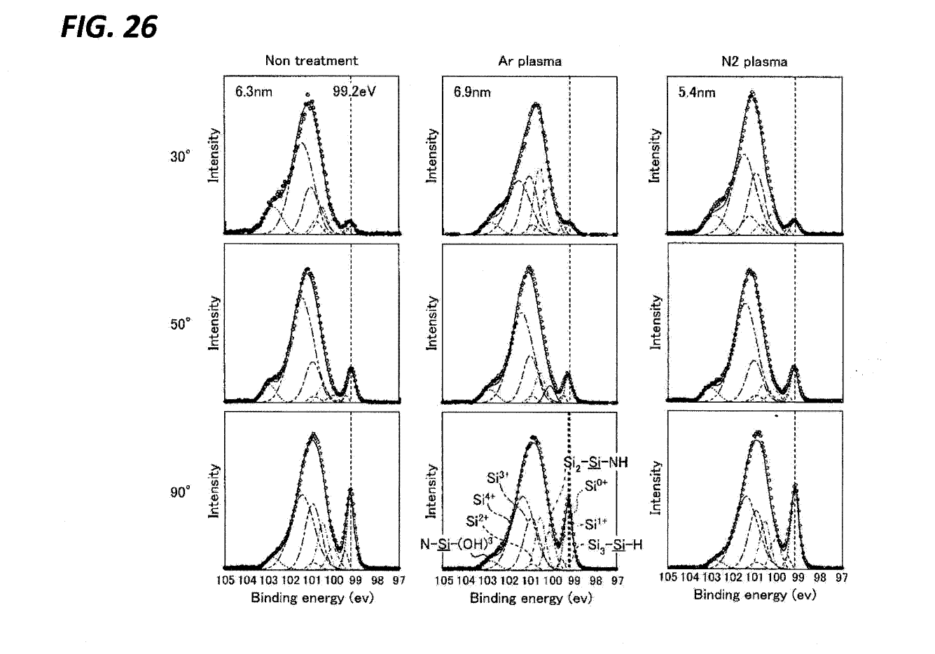

FIG. 26 is a view illustrating a waveform separation result of Si 2p 3/2 spectrum in the same manner as FIG. 18 illustrated in Example 1. Vertically three graphs in the left column of FIG. 26 correspond to a comparative sample obtained without performing a DCS adsorption pre-treatment. Vertically three graphs in the middle column of FIG. 26 correspond to a test sample obtained by an Ar plasma DCS adsorption pre-treatment. Vertically three graphs in the right column of FIG. 26 correspond to a test sample obtained by performing a N₂ plasma DCS adsorption pre-treatment.

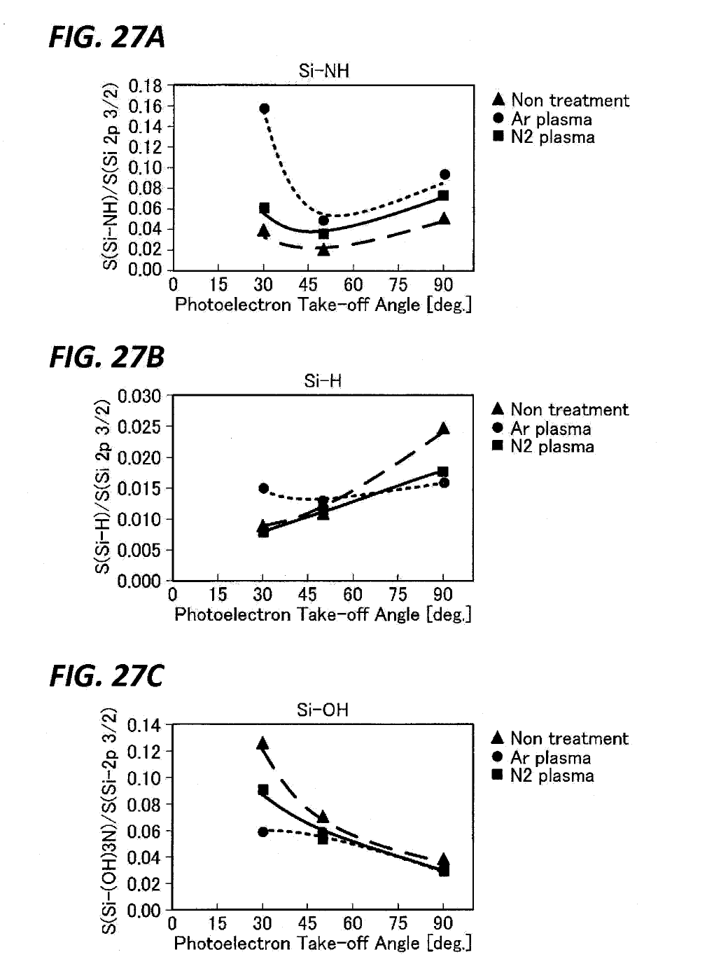

As illustrated in FIG. 26, the test sample obtained by the Ar plasma DCS adsorption pre-treatment has the largest separated peak area of Si—NH at TOA of 30°. That is, in the test sample obtained by the Ar plasma DCS adsorption pre-treatment, a signal intensity of Si—NH bonds is stronger than those in other samples. In order to evaluate the ratio of the bonding state within the film, each separated peak area was standardized by a peak area of Si 2p 3/2 spectrum, and the results are illustrated in FIGS. 27A, 27B and 27C.

FIG. 27A is a view illustrating a relationship between a peak area of Si 2p 3/2 spectrum of Si—NH and a TOA in Example 2. FIG. 27B is a view illustrating a relationship between a peak area of Si 2p 3/2 spectrum of Si—H and a TOA in Example 2. FIG. 27C is a view illustrating a relationship between a peak area of Si 2p 3/2 spectrum of Si—OH and a TOA in Example 2.

As illustrated in FIG. 27A, the Si—NH bonds in the Ar plasma DCS adsorption pre-treatment were less dependent on the TOA and have a larger peak area ratio as compared to other conditions. This indicates an increase of Si—NH bonds within the film. Also, as illustrated in FIG. 27B, since the peak area of Si—H with respect to the total peak area is small, it may be said that a change amount of the total peak area according to a change amount of the peak area of Si—H is small.

Meanwhile, as illustrated in FIG. 27C, there was a difference in the Si—OH bonds between a case where a DCS adsorption pre-treatment was performed and a case where no DCS adsorption pre-treatment was performed. In a case where there was no DCS adsorption pre-treatment, as the TOA was decreased, the Si—OH intensity, i.e., a surface oxidation amount, was increased. In a case where there is the DCS adsorption pre-treatment, dependency of the peak area of the Si—OH bonds to the TOA is low. Accordingly, it is believed that the surface oxidation was suppressed by the DCS adsorption pre-treatment. The difference in Example 2 between a case where the DCS adsorption pre-treatment was performed and a case where no DCS adsorption pre-treatment was performed was not as much as the difference between a case where a plasma post-treatment was performed and where no plasma post-treatment was performed in Example 1.

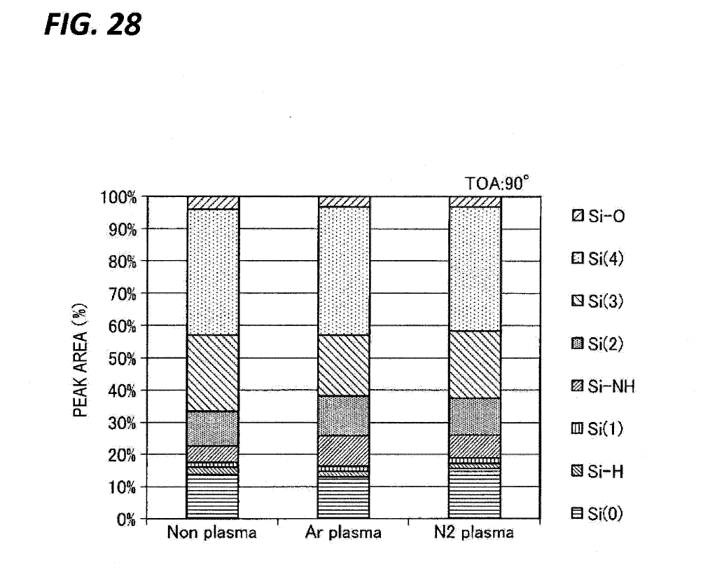

FIG. 28 is a view illustrating a comparison in a ratio of a peak area of Si 2p 3/2 spectrum in each constitutional component of a nitride film, between a case where Ar plasma was employed and a case where N₂ plasma was employed in the DCS adsorption pre-treatment. As illustrated in FIG. 28, when the TOA was 90°, there was little difference in a peak area ratio of each bond between no DCS adsorption pre-treatment, the Ar plasma DCS adsorption pre-treatment, and the N₂ plasma DCS adsorption pre-treatment. As can be seen from FIGS. 27A to 27C, when the TOA was reduced to 30°, the bonding strength of Si—NH was increased and the bonding strength of Si—OH was decreased. Accordingly, it may be said that a suppressing effect of surface oxidation by the DCS adsorption pre-treatment was large.

When there was no DCS adsorption pre-treatment, WERR1 was 1.86, when there was the Ar plasma DCS adsorption pre-treatment, WERR1 was 1.06, and when there was the N₂ plasma DCS adsorption pre-treatment, WERR1 was 1.48. Accordingly, it may be said that the Ar plasma DCS adsorption pre-treatment was most excellent. That is, it is estimated that the surface oxidation amount was correlated with WERR.

(Relationship Between Film Quality and Throughput)

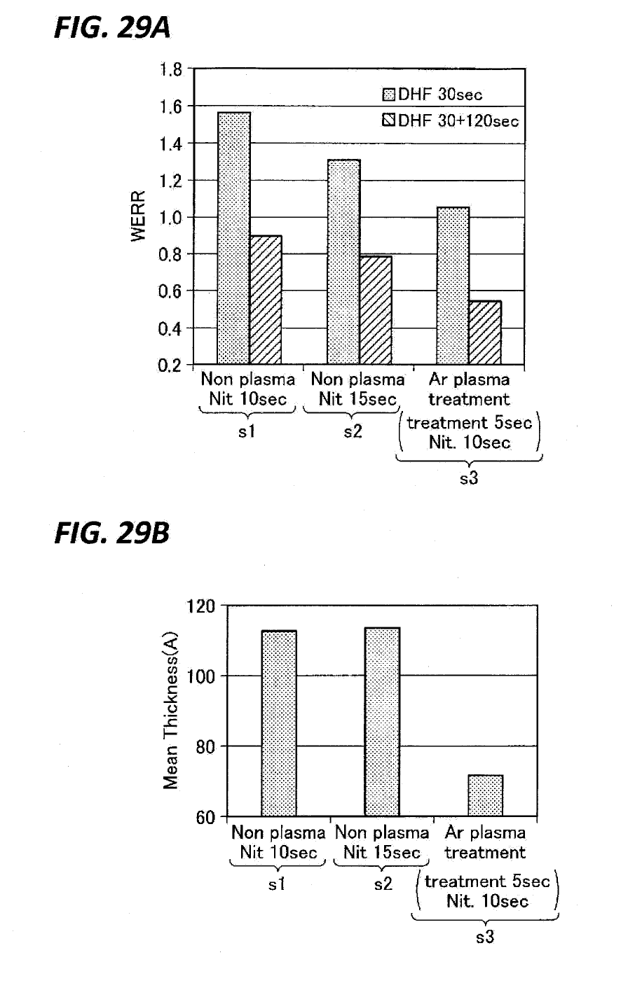

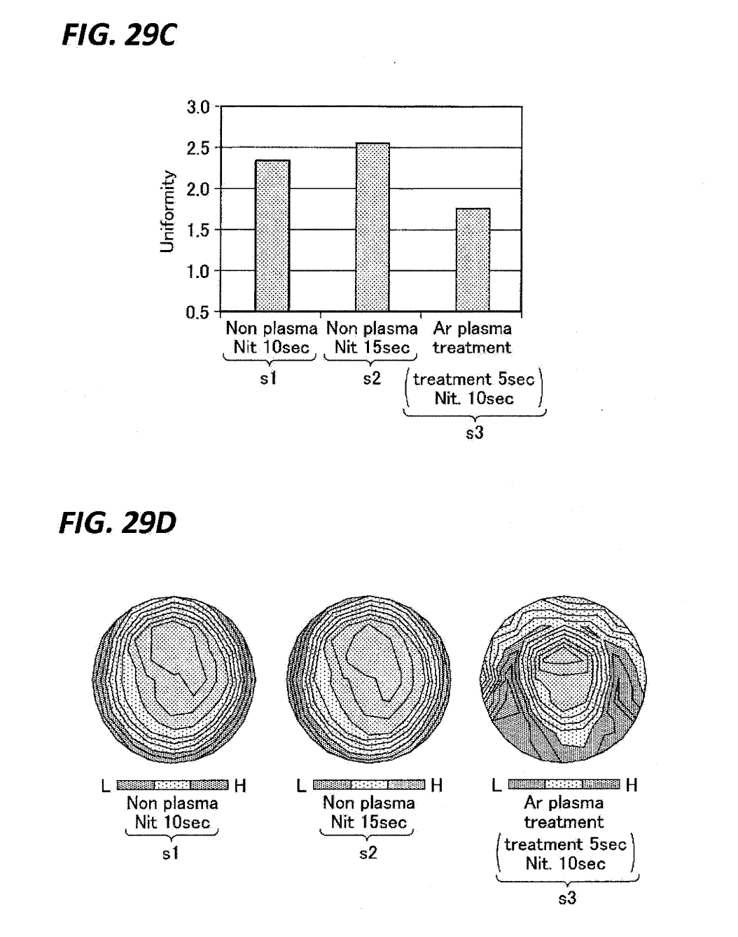

Referring to FIGS. 29A to 29D, descriptions will be made on the relationship between a film quality and a throughput per cycle. FIGS. 29A to 29D are views illustrating comparisons in a WERR, a film thickness average, a film thickness uniformity, and a film thickness distribution between a sample obtained by performing a plasma ALD treatment for 10 sec without a DCS adsorption pre-treatment, a sample obtained by performing a plasma ALD treatment for 15 sec without a DCS adsorption pre-treatment, and a sample obtained by performing a DCS adsorption pre-treatment for 5 sec and a plasma ALD treatment for 10 sec.

That is, FIGS. 29A to 29D are views illustrating comparisons between the following three samples (s1) to (s3). That is, the sample (s1) is a sample obtained by performing a plasma ALD treatment for 10 sec without a DCS adsorption pre-treatment, and corresponds to a graph of “Non plasma Nit. 10 sec” illustrated in FIGS. 29A to 29D. The sample (s2) is a sample obtained by performing a plasma ALD treatment for 15 sec without a DCS adsorption pre-treatment, and corresponds to a graph of “Non plasma Nit. 15 sec” illustrated in FIGS. 29A to 29D.

As indicated by “treatment 5 sec, Nit. 10 sec” in FIGS. 29A to 29D, the sample (s3) is a sample obtained by performing an Ar plasma DCS adsorption pre-treatment for 5 sec and a plasma ALD treatment for 10 sec and corresponds to a graph of “Ar plasma treatment” illustrated in FIGS. 29A to 29D. That is, the sample (s3) is obtained by a 15-sec treatment including the Ar plasma adsorption pre-treatment for 5 sec and the Ar plasma ALD treatment for 10 sec, as one cycle.

Accordingly, in FIG. 29A, dependency of WERR on the plasma ALD treatment time may be understood when the graphs of the above-described samples (s1) and (s2) are compared to each other. In FIG. 29A, when the graphs of the above-described samples (s2) and (s3) are compared to each other, dependency of WERR on presence or absence of the Ar plasma adsorption pre-treatment may be understood in a case where one cycle is performed in the same time.

The conditions of supplying a gas in the Ar plasma DCS adsorption pre-treatment in FIGS. 29A to 29D were as follows. That is, the modifier gas was Ar gas, and was supplied in an amount of 900 SCCM from the upper side, 500 SCCM from the lateral side, and 100 SCCM from the ALD ring.

As illustrated in FIG. 29A, as compared to that in the samples (s1) and (s2), WERR in the sample (s3) was improved. Meanwhile, both in the samples (s2) and (s3), the total treatment time is 15 sec. Accordingly, the treatment time per cycle is the same in both samples. However, as illustrated in FIG. 29A, WERR in the sample (s3) was better than that in the sample (s2). That is, according to FIG. 29A, it can be seen that when the treatment time per cycle was the same, the film quality was improved in a case where the plasma ALD treatment was performed together with the DCS adsorption pre-treatment.

As illustrated in FIG. 29B, as compared to those in the samples (s1) and (s2), the film thickness average in the sample (s3) was reduced. That is, according to FIG. 29B, it can be seen that when the treatment time per cycle was the same, the film thickness average was reduced in a case where the plasma ALD treatment was performed together with the DCS adsorption pre-treatment

As illustrated in FIGS. 29C and 29D, as compared to those in the samples (s1) and (s2), the film thickness uniformity in the sample (s3) was improved. That is, it can be seen that when the treatment time per cycle was the same, the film thickness uniformity in film thickness was improved in a case where the plasma ALD treatment was performed together with the DCS adsorption pre-treatment. Also, FIG. 29D is a view illustrating a film thickness distribution by contour lines in the same manner as in FIG. 25D.

That is, according to FIGS. 29A to 29D, it can be seen that the film quality is improved when the treatment time of plasma ALD is prolonged. When the treatment time per cycle was the same, the film quality and the film thickness uniformity were improved by performing the DCS adsorption pre-treatment and then the plasma ALD treatment in each cycle. However, when the treatment time per cycle was the same, in a case where the DCS adsorption pre-treatment was followed by the plasma ALD treatment in each cycle, it was required to further execute the treatment for 113 cycles in order to obtain the same film thickness as that in the plasma ALD treatment for 15 sec with no DCS adsorption pre-treatment. The further execution of the treatment for 113 cycles indicates that a treatment time required for film forming of one sample is increased about 1.5 times. That is, in the plasma ALD sequence following the DCS adsorption pre-treatment, the throughput with respect to film thickness, that is, the number of samples of a predetermined film thickness which may be formed per unit time, was about ⅔ of that in the plasma ALD sequence in which there is no DCS adsorption pre-treatment.

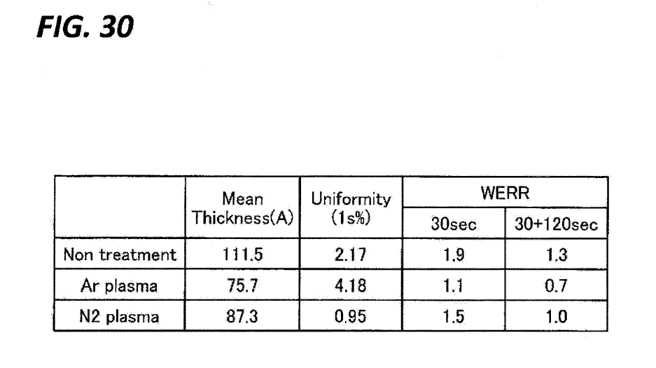

Accordingly, the results in Example 2 are as follows. FIG. 30 is a view illustrating a comparison of test results in Example 2. As illustrated in FIG. 30, when the DCS adsorption pre-treatment was included in the plasma ALD treatment, the film thickness uniformity, and both WERR1 and WERR2 were improved in both the Ar plasma DCS adsorption pre-treatment and N₂ plasma DCS adsorption pre-treatment. However, the film thickness of the nitride film was decreased. When a waveform separation of Si 2p 3/2 spectrum was performed by XPS, no significant difference was observed in the bonding state of atoms and molecules of the nitride film at TOA 90°. That is, the improvement of film quality was more significantly observed on or near the surface of the nitride film as compared to that in the inside of the nitride film.

### Example 3

In Example 3, descriptions will be made on a case where various rotation speeds are used when one or more combinations among an adsorption step, a first reaction step, and a second reaction step are performed by rotating the mounting table 14. Specifically, hereinafter, descriptions will be made on a case where various rotation speeds are used when a plasma ALD sequence including the adsorption step and the first reaction step is continuously performed by rotating the mounting table 14.

In Tests 3 to 5, as execution conditions of a plasma ALD sequence of forming a nitride film on the surface of a silicon wafer, the following conditions were used. As for the reaction gas, a mixed gas of NH₃/Ar was used. The pressure when forming a film was 5 Torr. The microwave power supplied when forming a film was 4 kW. The rotation speeds in Tests 3 to 5 were 5 rpm, 10 rpm, and 20 rpm, respectively, and the plasma ALD sequence was repeated 300 cycles.

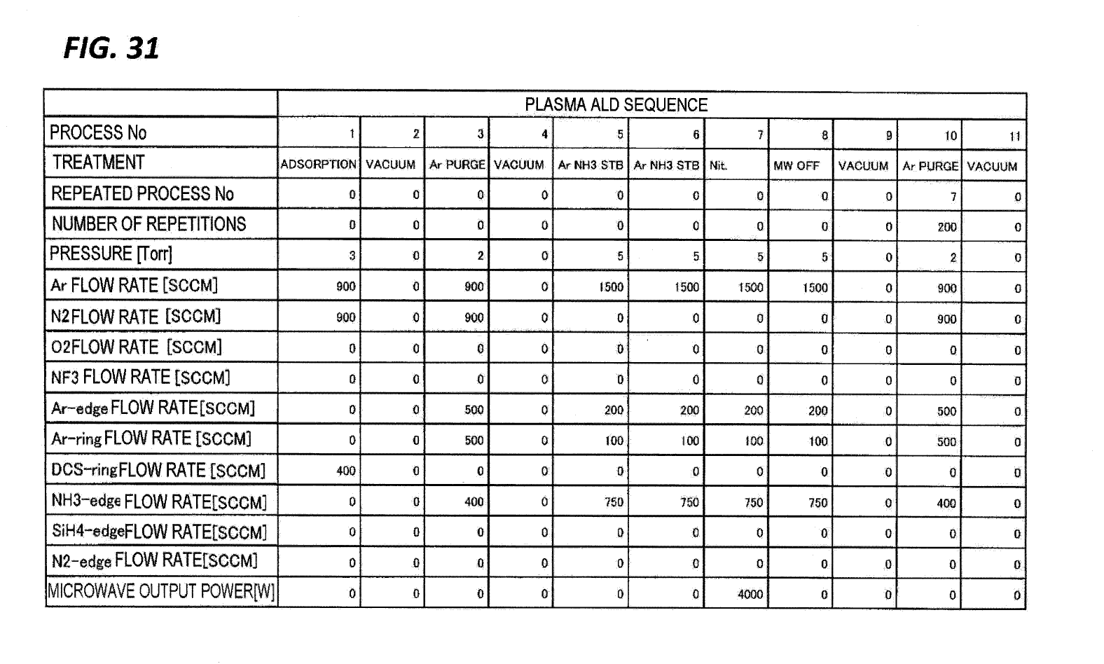

FIG. 31 is a view illustrating a test recipe related to Example 3. In Tests 3 to 5, the tests were performed according to the test recipe illustrated in FIG. 31. More specifically, in Tests 3 to 5, a series of processes described in the test recipe was performed once while the mounting table 14 was rotated once.

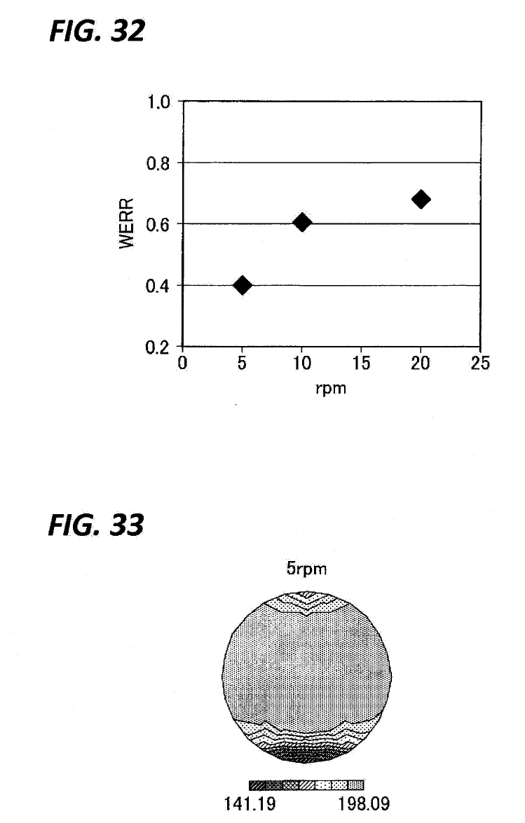

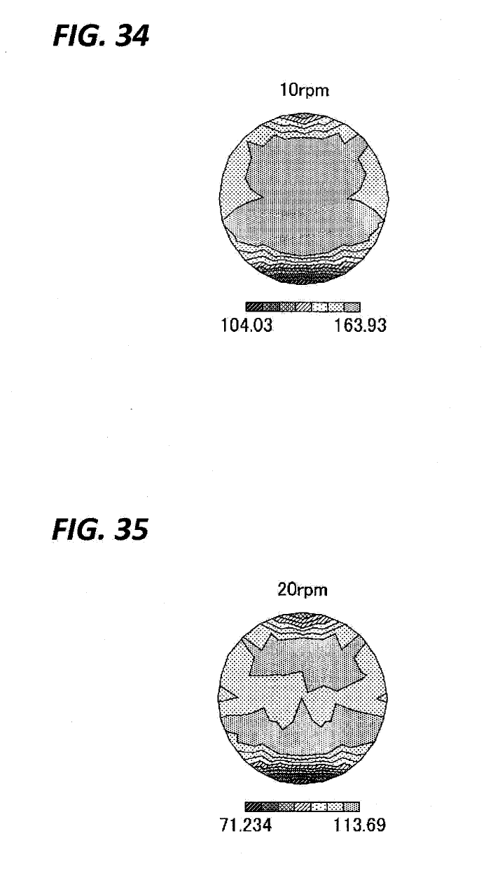

Referring to FIGS. 32 to 36, the relationship between a rotation speed, a film quality and a film uniformity will be described. FIGS. 32 to 36 are views illustrating the results of Tests 3 to 5. FIG. 32 is a view illustrating a relationship between a film uniformity and a film thickness in Tests 3 to 5. As illustrated in FIG. 32, as the rotation speed was decreased, the film thickness became thicker, and the uniformity was improved. FIGS. 33 to 35 are views illustrating film thickness distribution in Tests 3 to 5, respectively, by contour lines.

No significant difference was observed between the film thickness uniformity and the WERRR when the speed was in a range of 20 to 10 rpm. However, when the speed is reduced to 5 rpm, the uniformity and the WERR are significantly improved. Meanwhile, the throughput is degraded at a low rotation speed. Since the cycle rates at 5 rpm, 10 rpm, and 20 rpm are 0.63 A/cycle, 0.51 A/cycle, and 0.35 A/cycle, respectively, when a target film thickness is set to 10 nm, the numbers of film-formed sheets per hour are about 10, 15, and 20 sheets, respectively. As described above, since the uniformity and the WERR, and the throughput have a trade-off relationship, it is difficult to unconditionally determine what rotation speed is optimum because it is varied depending on required film forming contents.

### DESCRIPTION OF SYMBOL

C: processing chamber, W: substrate, 10, 10a, 100, 100a: film forming apparatus, 12, 112: processing container, 14, 114: mounting table, 16: first gas supply section, 18: exhaust section, 20: second gas supply section, 22: plasma generating section, 22b: third gas supply section, 24: driving mechanism, 24a: driving device, 34, 52: exhaust device, 40w, 140w: dielectric window, 40, 140: dielectric plate, 48, 148: microwave generator, 60, 160: control unit, 116, 120, 130: gas supply section

1. A film forming process of atomic layer deposition (ALD) that forms a film by causing a first gas to be adsorbed on a substrate, and to be reacted with active species of a second gas using a film forming apparatus, the film forming process comprising:
a step in which the substrate is placed;
an adsorption step in which a precursor gas is chemically adsorbed on a surface of the substrate to form an adsorption layer;
a first reaction step in which a first active species is generated by generating plasma of a reaction gas, and the adsorption layer is reacted with the first active species to form a film; and
a second reaction step in which a second active species is generated by generating plasma of a modifier gas, and the film is modified by the second active species.

2. The film forming process of claim 1, wherein the modifier gas in the second reaction step is at least one of a nitrogen-containing gas and a rare gas.

3. The film forming process of claim 1, wherein the film forming apparatus includes a processing container, and the processing container includes:
a first region configured to supply the precursor gas,
a second region configured to supply the reaction gas, and
a mounting table disposed within the processing container and configured to mount a plurality of substrates thereon,
wherein the substrates are mounted on the mounting table around a central axis of the mounting table and the mounting table is rotatable in a circumferential direction around the central axis, and
the adsorption step, the first reaction step, and the second reaction step are performed by rotating the mounting table.

4. The film forming process of claim 1, further comprising, before the second reaction step, a third reaction step in which plasma of a gas containing at least one of an argon gas and a nitrogen gas is generated and reacted with the surface of the substrate.

5. The film forming process of claim 1, wherein the adsorption step and the first reaction step are sequentially repeated to form a desired film thickness, and then the second reaction step is performed.

6. The film forming process of claim 1, wherein the adsorption step, the first reaction step, and the second reaction step are sequentially repeated to form a desired film thickness.

7. A film forming process performed by a film forming apparatus configured to form a film on a surface of a substrate, the film forming process comprising:
an adsorption step in which a precursor gas is chemically adsorbed on the surface of the substrate mounted on a mounting table provided within a hermetically sealed processing container;
a first reaction step in which a reaction gas is supplied into the processing container to generate plasma of the reaction gas, and the plasma of the reaction gas is reacted with the surface of the substrate; and
a second reaction step in which any of an ammonia gas, an argon gas, a nitrogen gas, and a hydrogen gas, or a gas obtained by mixing the ammonia gas, the argon gas, the nitrogen gas, and the hydrogen gas is supplied as a modifier gas into the processing container to generate plasma of the modifier gas, and the plasma of the modifier gas is reacted with the surface of the substrate.

8. The film forming process of claim 7, wherein the mounting table is formed in a substantially circular shape and includes a plurality of substrate mounting regions around a central axis, the substrate being mounted on any of the substrate mounting regions and the mounting table being rotatable in a circumferential direction around the central axis, and
one or more combinations of the adsorption step, the first reaction step, and the second reaction step are performed by rotating the mounting table.

9. The film forming process of claim 7, further comprising, before the second reaction step, a third reaction step in which a gas containing at least one of an argon gas and a nitrogen gas is supplied into the processing container to generate plasma of the supplied gas, and the plasma is reacted with the surface of the substrate.

10. The film forming process of claim 7, wherein the film forming apparatus performs the adsorption step and the first reaction step sequentially and repeatedly and then, performs the second reaction step.

11. The film forming process of claim 10, wherein the film forming apparatus repeatedly performs a series of treatments to perform the second reaction step after performing the adsorption step and the first reaction step sequentially and repeatedly.

12. The film forming process of claim 7, wherein the film forming apparatus performs the adsorption step, the first reaction step and the second reaction step sequentially and continuously.

13. The film forming process of claim 7, wherein the film forming apparatus performs a series of treatments to perform the adsorption step, the first reaction step and the second reaction step sequentially and continuously, and performs a series of treatments to perform the second reaction step after performing the adsorption step and the first reaction step sequentially and repeatedly.

14. A film forming apparatus comprising:
a hermetically sealed processing container;
a mounting table provided within the processing container and configured to mount a substrate thereon;
a supply unit configured to supply a precursor gas, a reaction gas, and a modifier gas which is any of an ammonia gas, an argon gas, a nitrogen gas, and a hydrogen gas, or a gas obtained by mixing the ammonia gas, the argon gas, the nitrogen gas, and the hydrogen gas into the processing container;
a plasma generating section configured to generate plasma of the reaction gas and the modifier gas which are supplied into the processing container by the supply unit; and
a control unit configured to perform an adsorption step, a first reaction step, and a second reaction step, wherein in the adsorption step, the control unit controls the supply unit to supply the precursor gas into the processing container so that the precursor gas is chemically adsorbed on a surface of the substrate, in the first reaction step, the control unit controls the supply unit to supply the reaction gas into the processing container and controls the plasma generating section to generate plasma of the reaction gas so that the surface of the substrate is reacted with the plasma of the reaction gas, and in the second reaction step, the control unit controls the supply unit to supply the modifier gas into the processing container, and controls the plasma generating section to generate plasma of the modifier gas so that the surface of the substrate is reacted with the plasma of the modifier gas.

15. The film forming apparatus of claim 14, wherein the mounting table is formed in a substantially circular shape and includes a plurality of substrate mounting regions around a central axis, the substrate being mounted on any of the substrate mounting region and the mounting table being rotatable in a circumferential direction around the central axis, and
one or more combinations of the adsorption step, the first reaction step, and the second reaction step are performed by rotating the mounting table.

16. The film forming apparatus of claim 14, wherein the control unit performs, before the second reaction step, a third reaction step in which a gas containing at least one of an argon gas and a nitrogen gas is supplied into the processing container to generate plasma of the supplied gas, and the plasma is reacted with the surface of the substrate.

17. The film forming apparatus of claim 14, wherein the mounting table is formed in a substantially circular shape and includes substrate mounting regions around a central axis, the substrate being mounted on any of the substrate mounting regions and the mounting table being rotatable in a circumferential direction around the central axis,
the processing container includes a first region and a second region through which the substrate mounting regions sequentially pass, the substrate mounting regions moving in the circumferential direction around the central axis by rotating the mounting table,
the supply unit includes a first supply unit configured to supply the precursor gas from an injection section provided to face the mounting table in the first region, and a second supply unit configured to supply the reaction gas and the modifier gas from an injection section provided to face the mounting table in the second region, and
the plasma generating section is provided to face the mounting table in the second region, and is configured to generate plasma of the reaction gas and the modifier gas in the second region.

18. The film forming apparatus of claim 17, wherein the control unit repeatedly performs a series of treatments to perform the second reaction step after performing the adsorption step and the first reaction step sequentially and repeatedly.

19. The film forming apparatus of claim 14, wherein the control unit performs the adsorption step, the first reaction step and the second reaction step sequentially and continuously.

20. The film forming apparatus of claim 14, wherein the control unit performs a series of treatments to perform the adsorption step, the first reaction step, and the second reaction step sequentially and continuously, and performs a series of treatments to perform the second reaction step after performing the adsorption step and the first reaction step sequentially and repeatedly.
